(19) United States
(12) Patent Application Publication
(10) Pub. No.: US 2020/0201181 A1
(43) Pub. Date: Jun. 25, 2020

(54) NEGATIVE-TONE PHOTOSENSITIVE RESIN COMPOSITION, PHOTOSENSITIVE RESIST FILM, AND METHOD OF FORMING PATTERN

(71) Applicant: TOKYO OHKA KOGYO CO., LTD., Kawasaki-shi (JP)

(72) Inventors: Hirofumi IMAI, Kawasaki-shi (JP); Ryuma MIZUSAWA, Kawasaki-shi (JP); Ryosuke NAKAMURA, Kawasaki-shi (JP); Takahiro KONDO, Kawasaki-shi (JP)

(21) Appl. No.: 16/701,720

(22) Filed: Dec. 3, 2019

(30) Foreign Application Priority Data
Dec. 21, 2018 (JP) 2018-240352

(51) Int. Cl. G03F 7/038; G03F 7/085

(52) U.S. Cl. CPC G03F 7/0382; G03F 7/16; G03F 7/085

(57) ABSTRACT

A negative-tone photosensitive resin composition containing an epoxy group-containing resin, a cationic polymerization initiator, and a polyfunctional thiol compound.

### BACKGROUND OF THE INVENTION

### Field of the Invention

The present invention relates to a negative-tone photosensitive resin composition, a photosensitive resist film having a photosensitive resin film formed by using the negative-tone photosensitive resin composition, and a method of forming pattern.

Priority is claimed on Japanese Patent Application No. 2018-240352, filed on Dec. 21, 2018, the content of which is incorporated herein by reference.

### Description of Related Art

In the wake of miniaturization and densification of electronic devices in recent years, demands for photosensitive dry films used in production of LSI and the like are increased.

For example, by using a photosensitive dry film by adhering the photosensitive dry film on a surface of a semiconductor wafer and the like, performing selective exposure with light and radiation such as electron beams, performing development treatment to form a pattern, and then performing pressure-bonding with a transparent substrate (for example, glass substrate) and the like, it is possible to use the photosensitive dry film as a spacer between the semiconductor wafer and the transparent substrate.

A photosensitive resin layer of the photosensitive dry film is required to be a layer which includes a photosensitive material, can be patterned by a photolithography method, and allows maintenance of a shape as a spacer and the like.

In addition, since pressure-bonding with the transparent substrate is performed after exposure and development, a layer excellent in not only developability and resolution but also adhesion properties after patterning is required.

In the related art, as a negative-tone photosensitive composition used in the photosensitive dry film, a composition containing a base component formed of a novolac resin and an acid generator component such as diazonaphthoquinone was used.

However, since a diazonaphthoquinone type photoacid generator exhibits absorption with respect to a wavelength of light used in exposure, there is a problem in that light intensity due to exposure is different between an upper portion and a lower portion (in the vicinity of interface with substrate) of a thick resist film, and the shape of the obtained pattern is not a desired shape such as rectangle.

With respect to this, in recent years, as a negative-tone photosensitive composition for a thick resist or a photosensitive dry film, a composition containing a base component containing an epoxy group and a cationic polymerization initiator is used.

As the cationic polymerization initiator, a fluorinated antimony-based cationic polymerization initiator having high sensitivity to light (for example, polymerization initiator having SbF₆⁻ on the anion moiety) is widely used.

For example, in Patent Literature 1, there is proposed a photosensitive resin composition that has improved coating uniformity, does not cause variation in pattern dimension, and can form a fine resist pattern having a high film thickness and a high aspect ratio, obtained by adding a silicone-based surfactant to a photosensitive resin composition containing a polyfunctional epoxy resin and a cationic polymerization initiator.

### DOCUMENTS OF RELATED ART

### Patent Literature

[Patent Literature 1] Japanese Unexamined Patent Application, First Publication No. 2008-250200

### SUMMARY OF THE INVENTION

However, in the negative-tone photosensitive resin composition in the related art, adhesion properties to a surface of a support (in particular, metal substrate such as Cu, Au, and Cr) were poor, and even in a case where resolution of a resist itself was possible, peeling easily occurred, and thus fine pattern formation was difficult. Therefore, in a case where patterning was performed on the support in the related art, surface treatment and the like, such as forming a thermal oxide film on a surface or forming a separate organic film on a surface as an adhesion layer, were required to ensure adhesion properties.

The present invention has been made in consideration of the above-described problems, and an object of the present invention is to provide a negative-tone photosensitive resin composition which has excellent adhesion properties to a support and is capable of forming a fine pattern, a photosensitive resist film including a photosensitive resin film formed by using thereof, and a method of forming pattern.

In order to obtain the object, the present invention employs the following configuration.

That is, according to a first aspect of the present invention, there is provided a negative-tone photosensitive resin composition including an epoxy group-containing resin (A), a cationic polymerization initiator (I), and a polyfunctional thiol compound (T).

According to a second aspect of the present invention, there is provided a photosensitive resist film comprising a base film, a photosensitive resin film formed from the negative-tone photosensitive resin composition according to the first aspect, and a cover film laminated in this order.

According to a third aspect of the present invention, there is provided a method of forming pattern including: a step of forming a photosensitive resin film on a support using the negative-tone photosensitive resin composition according to the first aspect or the photosensitive resist film according to the second aspect; a step of exposing the photosensitive resin film; and a step of developing the exposed photosensitive resin film to form a negative-tone pattern.

According to the negative-tone photosensitive resin composition of the present invention, it is possible to provide a negative-tone photosensitive resin composition which has excellent adhesion properties to a support and is capable of forming a fine pattern, a photosensitive resist film including a photosensitive resin film formed by using thereof, and a method of forming pattern.

### DETAILED DESCRIPTION OF THE INVENTION

In the present specification and claims, the term “aliphatic” is a relative concept used with respect to the term “aromatic” and defines a group, a compound, or the like with no aromaticity.

The term “alkyl group” includes linear, branched, or cyclic monovalent saturated hydrocarbon groups unless otherwise specified. The same applies to the alkyl group in an alkoxy group.

The term “alkylene group” includes linear, branched, or cyclic divalent saturated hydrocarbon groups unless otherwise specified.

A “halogenated alkyl group” is a group in which some or all hydrogen atoms in an alkyl group are substituted with halogen atoms. Examples of the halogen atom include a fluorine atom, a chlorine atom, a bromine atom, and an iodine atom.

A “fluorinated alkyl group” or a “fluorinated alkylene group” is a group in which some or all hydrogen atoms in an alkyl group or alkylene group are substituted with fluorine atoms.

The term “constitutional unit” indicates a monomer unit constituting a polymer compound (a resin, a polymer, or a copolymer).

The expression “may have a substituent” includes a case where a hydrogen atom (—H) is substituted with a monovalent group and a case where a methylene group (—CH₂—) is substituted with a divalent group.

The term “exposure” is used as a general concept for irradiation with radiation.

In the present specification and claims, depending on a structure represented by a chemical formula, there is a case where an asymmetric carbon is present, and thus an enantiomer and a diastereomer can be present. In this case, these isomers are represented by one chemical formula. These isomers may be used alone, or may be used as a mixture.

(Negative-Tone Photosensitive Resin Composition)

A negative-tone photosensitive resin composition (hereinafter, simply referred to as a “photosensitive composition”) according to the present embodiment contains an epoxy group-containing resin (A), a cationic polymerization initiator (I), and a polyfunctional thiol compound (T). Hereinafter, these components are referred to as a component (A), a component (I), and a component (T).

In a case where a photosensitive resin film is formed using such a photosensitive composition and selective exposure is performed on the photosensitive resin film, since a cation moiety of the component (I) is decomposed to generate an acid in an exposed portion of the photosensitive resin film, and an epoxy group in the component (A) is subjected to ring-opening polymerization due to an action of the acid so that the solubility of the component (A) in a developing solution is decreased while the solubility of the component (A) in a developing solution is not changed in an unexposed portion of the photosensitive resin film, a difference between the solubility of the exposed portion of the photosensitive resin film in a developing solution and the unexposed portion thereof in a developing solution is generated. Therefore, in a case where the photosensitive resin film is developed, an unexposed portion is dissolved and removed so that a negative-tone pattern is formed.

<Epoxy Group-Containing Resin (A)>

The epoxy group-containing resin (component (A)) is not particularly limited as long as the resin contains an epoxy group sufficient enough to form a pattern upon exposure, in one molecule.

Examples of the component (A) include a novolac epoxy resin (Anv), a bisphenol A type epoxy resin (Abp), a bisphenol F type epoxy resin, an aliphatic epoxy resin, and an acrylic resin (Aac).

<<Novolac Epoxy Resin (Anv)>>

Suitable examples of the novolac epoxy resin (Anv) include a resin (hereinafter, also referred to as a “component (A1)”) represented by Formula (A1).

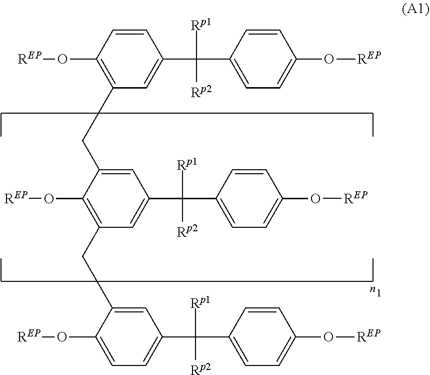

[In Formula, R^{p1} and R^{p2} each independently represent a hydrogen atom or an alkyl group having 1 to 5 carbon atoms. A plurality of R^{p1}'s may be the same as or different from one another. A plurality of R^{p2}'s may be the same as or different from one another. n₁ represents an integer of 1 to 5. R^{EP} represents an epoxy group-containing group. A plurality of R^{EP}'s may be the same as or different from one another.]

In Formula (A1), the alkyl group having 1 to 5 carbon atoms as R^{p1} and R^{p2} is, for example, a linear, branched, or cyclic alkyl group having 1 to 5 carbon atoms. Examples of the linear or branched alkyl group include a methyl group, an ethyl group, a propyl group, an isopropyl group, an n-butyl group, an isobutyl group, a tert-butyl group, a pentyl group, an isopentyl group, and a neopentyl group. Further, examples of the cyclic alkyl group include a cyclobutyl group and a cyclopentyl group.

Among the example, R^{p1} and R^{p2} represent preferably a hydrogen atom or a linear or branched alkyl group, more preferably a hydrogen atom or a linear alkyl group, and particularly preferably a hydrogen atom or a methyl group.

In Formula (A1), a plurality of R^{p1}'s may be the same as or different from one another. A plurality of R^{p2}'s may be the same as or different from one another.

In Formula (A1), n₁ represents an integer of 1 to 5, preferably 2 or 3, and more preferably 2.

In Formula (A1), R^{EP} represents an epoxy group-containing group.

The epoxy group-containing group as R^{EP} is not particularly limited, and examples thereof include a group formed of only an epoxy group; a group formed of only an alicyclic epoxy group; and a group containing an epoxy group or an alicyclic epoxy group and a divalent linking group.

The alicyclic epoxy group is an alicyclic group having an oxacyclopropane structure as a three-membered ring ether. Specifically, the alicyclic epoxy group is a group having an alicyclic group and an oxacyclopropane structure. The alicyclic group which becomes a basic skeleton of the alicyclic epoxy group may be monocyclic or polycyclic. Examples of the monocyclic alicyclic group include a cyclopropyl group, a cyclobutyl group, a cyclopentyl group, a cyclohexyl group, a cycloheptyl group, and a cyclooctyl group. Further, examples of the polycyclic alicyclic group include a norbomyl group, an isobornyl group, a tricyclononyl group, a tricyclodecyl group, and a tetracyclododecyl group. Further, a hydrogen atom in these alicyclic groups may be substituted with an alkyl group, an alkoxy group, a hydroxyl group, and the like.

In a case of the group containing an epoxy group or an alicyclic epoxy group and a divalent linking group, it is preferable that an epoxy group or an alicyclic epoxy group is bonded through a divalent linking group bonded to an oxygen atom (—O—) in the formula.

Here, the divalent linking group is not particularly limited, and suitable examples thereof include a divalent hydrocarbon group which may have a substituent and a divalent linking group having a hetero atom.

Regarding divalent hydrocarbon group which may have substituent:

Such a divalent hydrocarbon group may be an aliphatic hydrocarbon group or an aromatic hydrocarbon group.

The aliphatic hydrocarbon group in the divalent hydrocarbon group may be saturated or unsaturated. In general, it is preferable that the aliphatic hydrocarbon group is saturated.

More specific examples of the aliphatic hydrocarbon group include a linear or branched aliphatic hydrocarbon group and an aliphatic hydrocarbon group containing a ring in the structure thereof.

The number of carbon atoms in the linear aliphatic hydrocarbon group is preferably in a range of 1 to 10, more preferably in a range of 1 to 6, still more preferably in a range of 1 to 4, and most preferably in a range of 1 to 3. As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄-] and a pentamethylene group [—(CH₂)₅—]. The number of carbon atoms of the branched aliphatic hydrocarbon group is preferably in a range of 2 to 10, more preferably in a range of 2 to 6, still more preferably in a range of 2 to 4, and most preferably 2 or 3. As the branched aliphatic hydrocarbon group, a branched alkylene group is preferable. Specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Examples of the aliphatic hydrocarbon group containing a ring in the structure thereof include an alicyclic hydrocarbon group (a group formed by removing two hydrogen atoms from an aliphatic hydrocarbon ring), a group in which an alicyclic hydrocarbon group is bonded to the terminal of a linear or branched aliphatic hydrocarbon group, and a group in which an alicyclic hydrocarbon group is interposed in a linear or branched aliphatic hydrocarbon group. Examples of the linear or branched aliphatic hydrocarbon group include the same as those described above.

The number of carbon atoms in the alicyclic hydrocarbon group is preferably in a range of 3 to 20 and more preferably in a range of 3 to 12.

The alicyclic hydrocarbon group may be a monocyclic group or a polycyclic group. As the monocyclic alicyclic hydrocarbon group, a group formed by removing two hydrogen atoms from a monocycloalkane is preferable. The number of carbon atoms of the monocycloalkane is preferably in a range of 3 to 6, and specific examples of such a monocycloalkane include cyclopentane and cyclohexane.

As the polycyclic alicyclic hydrocarbon group, a group formed by removing two hydrogen atoms from a polycycloalkane is preferable. The number of carbon atoms of the polycycloalkane is preferably in a range of 7 to 12, and specific examples of such a polycycloalkane include adamantane, norbomane, isobornane, tricyclodecane, and tetracyclododecane.

The aromatic hydrocarbon group in the divalent hydrocarbon group is a hydrocarbon group having at least one aromatic ring. The aromatic ring is not particularly limited as long as the aromatic ring has a cyclic conjugated system having (4n+2) π electrons, and may be monocyclic or polycyclic. The number of carbon atoms of the aromatic ring is preferably in a range of 5 to 30, more preferably in a range of 5 to 20, still more preferably in a range of 6 to 15, and particularly preferably in a range of 6 to 12. Specific examples of the aromatic ring include an aromatic hydrocarbon ring such as benzene, naphthalene, anthracene, or phenanthrene; and an aromatic heterocyclic ring in which some carbon atoms constituting the aromatic hydrocarbon ring are substituted with a hetero atom. Examples of the hetero atom in the aromatic heterocyclic ring include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) formed by removing two hydrogen atoms from the aromatic hydrocarbon ring or the aromatic heterocyclic ring; a group formed by removing two hydrogen atoms from an aromatic compound (biphenyl, fluorene, or the like) having two or more aromatic rings; and a group (a group in which one hydrogen atom is further removed from an aryl group in an arylalkyl group such as a benzyl group, a phenethyl group, a 1-naphthylmethyl group, a 2-naphthylmethyl group, a 1-naphthylethyl group, or a 2-naphthylethyl group) in which one hydrogen atom of a group (an aryl group or a heteroaryl group) formed by removing one hydrogen atom from the aromatic hydrocarbon ring or the aromatic heterocyclic ring is substituted with an alkylene group. The number of carbon atoms of the alkylene group which is bonded to the above-described aryl group or heteroaryl group is preferably in a range of 1 to 4, more preferably 1 or 2, and particularly preferably 1.

The divalent hydrocarbon group may have a substituent.

The linear or branched aliphatic hydrocarbon group as the divalent hydrocarbon group may or may not have a substituent. Examples of the substituent include a fluorine atom, a fluorinated alkyl group having 1 to 5 carbon atoms which is substituted with a fluorine atom, and a carbonyl group.

The alicyclic hydrocarbon group in an aliphatic hydrocarbon group containing a ring in the structure thereof, as the divalent hydrocarbon group, may or may not have a substituent. Examples of the substituent include an alkyl group, an alkoxy group, a halogen atom, a halogenated alkyl group, a hydroxyl group, and a carbonyl group.

As the alkyl group as the substituent, an alkyl group having 1 to 5 carbon atoms is preferable, and a methyl group, an ethyl group, a propyl group, an n-butyl group, or a tert-butyl group is most preferable.

As the alkoxy group as the substituent, an alkoxy group having 1 to 5 carbon atoms is preferable, a methoxy group, an ethoxy group, an n-propoxy group, an iso-propoxy group, an n-butoxy group, or a tert-butoxy group is preferable, and a methoxy group or an ethoxy group is most preferable.

Examples of the halogen atom as the substituent include a fluorine atom, a chlorine atom, a bromine atom, and an iodine atom. Among these, a fluorine atom is preferable.

Examples of the halogenated alkyl group as the substituent include a group in which some or all hydrogen atoms in the alkyl group are substituted with the halogen atoms. In the alicyclic hydrocarbon group, some carbon atoms constituting the ring structure thereof may be substituted with a substituent having a hetero atom. As the substituent having a hetero atom, —O—, —C(═O)—O—, —S—, —S(═O)₂—, or —S(═O)₂—O— is preferable.

In the aromatic hydrocarbon group as the divalent hydrocarbon group, a hydrogen atom in the aromatic hydrocarbon group may be substituted with a substituent. For example, the hydrogen atom bonded to the aromatic ring in the aromatic hydrocarbon group may be substituted with a substituent. Examples of the substituent include an alkyl group, an alkoxy group, a halogen atom, a halogenated alkyl group, and a hydroxyl group.

As the alkyl group as the substituent, an alkyl group having 1 to 5 carbon atoms is preferable, and a methyl group, an ethyl group, a propyl group, an n-butyl group, or a tert-butyl group is most preferable.

Examples of the alkoxy group, the halogen atom, and the halogenated alkyl group as the substituent include the same as those exemplified as the substituent for substituting the hydrogen atom in the alicyclic hydrocarbon group.

Regarding divalent linking group having hetero atom:

The hetero atom in the divalent linking group having a hetero atom is an atom other than a carbon atom and a hydrogen atom, and examples thereof include an oxygen atom, a nitrogen atom, a sulfur atom, and a halogen atom.

In the divalent linking group having a hetero atom, preferred examples of the linking group include —O—, —C(═O)—O—, —C(═O)—, —O—C(═O)—O—; —C(═O)—NH—, —NH—, —NH—C(═O)—O—, —NH—C(═NH)— (H may be substituted with a substituent such as an alkyl group, an acyl group, or the like); —S—, —S(═O)₂—, —S(═O)₂—O—, and a group represented by Formulae —Y²¹—O—Y²²—, —Y²¹—O—, —Y²¹—C(═O)—O—, —C(═O)—O—Y²¹—, —[Y²¹—C(═O)—O]_{m″}—Y²²—, or —Y²¹—O—C(═O)—Y²²— [in Formulae, Y²¹ and Y²² each independently represent a divalent hydrocarbon group which may have a substituent, O represents an oxygen atom, and m″ represents an integer of 0 to 3].

In a case where the divalent linking group having a hetero atom is —C(═O)—NH—, —NH—, —NH—C(═O)—O—, or —NH—C(═NH)—, H may be substituted with a substituent such as an alkyl group, an acyl group, or the like. The substituent (an alkyl group, an acyl group, or the like) has preferably 1 to 10 carbon atoms, more preferably 1 to 8 carbon atoms, and particularly preferably 1 to 5 carbon atoms.

In Formulae —Y²¹—O—Y²²—, —Y²¹—O—, —Y²¹—C(═O)—O—, —C(═O)—O—Y²¹—, —[Y²¹—C(═O)—O]_{m″}—Y²²—, or —Y²¹—O—C(═O)—Y²²—, Y²¹ and Y²² each independently represent a divalent hydrocarbon group which may have a substituent. Examples of the divalent hydrocarbon group include the same groups as those described above as the “divalent hydrocarbon group which may have a substituent” in the explanation of the above-described divalent linking group.

As Y²¹, a linear aliphatic hydrocarbon group is preferable, a linear alkylene group is more preferable, a linear alkylene group having 1 to 5 carbon atoms is still more preferable, and a methylene group or an ethylene group is particularly preferable.

As Y²², a linear or branched aliphatic hydrocarbon group is preferable, and a methylene group, an ethylene group, or an alkylmethylene group is more preferable. The alkyl group in the alkylmethylene group is preferably a linear alkyl group having 1 to 5 carbon atoms, more preferably a linear alkyl group having 1 to 3 carbon atoms, and most preferably a methyl group.

In the group represented by the formula —[Y²¹—C(═O)—O]_{m″}—Y²²—, m″ represents an integer of 0 to 3, preferably an integer of 0 to 2, more preferably 0 or 1, and particularly preferably 1. In other words, it is particularly preferable that the group represented by the formula —[Y²¹—C(═O)—O]_{m″}—Y²²— is a group represented by formula —Y²¹—C(═O)—O—Y²²—. Among these, a group represented by formula —(CH₂)_{a′}—C(═O)—O—(CH₂)_{b′}— is preferable. In the formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

Among these, a glycidyl group is preferable as the epoxy group-containing group in R^{EP}.

Further, suitable examples of the novolac epoxy resin (Anv) include a resin having a constitutional unit represented by Formula (anv1).

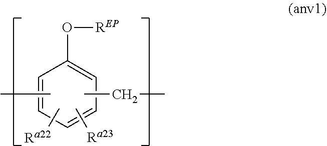

[In Formula, R^{EP} represents an epoxy group-containing group, and R^{a22} and R^{a23} each independently represent a hydrogen atom, an alkyl group having 1 to 5 carbon atoms, or a halogen atom.]

In Formula (anv1), the alkyl group having 1 to 5 carbon atoms as R^{a22} and R^{a23} has the same definition as the alkyl group having 1 to 5 carbon atoms as R^{p1} and R^{p2} in Formula (A1). It is preferable that the halogen atom as R^{a22} and R^{a23} is a chlorine atom or a bromine atom.

In Formula (anv1), R^{EP} has the same definition as that for R^{EP} in Formula (A1), and it is preferable that R^{EP} represents a glycidyl group.

Specific examples of the constitutional unit represented by Formula (anv1) are shown below.

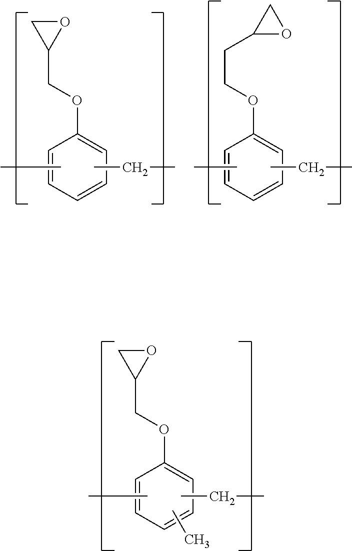

The novolac epoxy resin (Anv) may be a resin formed of only the constitutional unit (anv1) or a resin having the constitutional unit (anv1) and other constitutional units.

Examples of the other constitutional units include constitutional units represented by Formulae (anv2) and (anv3).

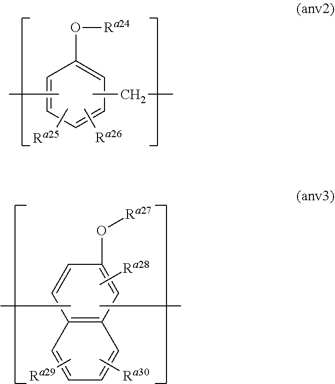

[In Formulae, R^{a24} represents a hydrocarbon group which may have a substituent. R^{a25} and R^{a26}, and R^{a28} to R^{a30} each independently represent a hydrogen atom, an alkyl group having 1 to 5 carbon atoms, or a halogen atom. R^{a27} represents an epoxy group-containing group or a hydrocarbon group which may have a substituent.]

In Formula (anv2), R^{a24} represents a hydrocarbon group which may have a substituent. Examples of the hydrocarbon group which may have a substituent include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group, a 1,1-diethylpropyl group, and a 2,2-dimethylbutyl group. Among these, an isopropyl group is preferable.

In a case where R^{a24} represents a cyclic hydrocarbon group, the cyclic hydrocarbon group may be an aliphatic hydrocarbon group or an aromatic hydrocarbon group, and may be a polycyclic group or a monocyclic group.

As the aliphatic hydrocarbon group which is a monocyclic group, a group formed by removing one hydrogen atom from a monocycloalkane is preferable. The number of carbon atoms of the monocycloalkane is preferably in a range of 3 to 6, and specific examples of such a monocycloalkane include cyclopentane and cyclohexane.

As the aliphatic hydrocarbon group which is a polycyclic group, a group formed by removing one hydrogen atom from a polycycloalkane is preferable. The number of carbon atoms of the polycycloalkane is preferably in a range of 7 to 12, and specific examples of such a polycycloalkane include adamantane, norbornane, isobornane, tricyclodecane, and tetracyclododecane.

In a case where the cyclic hydrocarbon group as R^{a24} is an aromatic hydrocarbon group, the aromatic hydrocarbon group is a hydrocarbon group having at least one aromatic ring.

The aromatic ring is not particularly limited as long as the aromatic ring has a cyclic conjugated system having (4n+2) π electrons, and may be monocyclic or polycyclic. The number of carbon atoms of the aromatic ring is preferably in a range of 5 to 30, more preferably in a range of 5 to 20, still more preferably in a range of 6 to 15, and particularly preferably in a range of 6 to 12. Specific examples of the aromatic ring include an aromatic hydrocarbon ring such as benzene, naphthalene, anthracene, or phenanthrene; and an aromatic heterocyclic ring in which some carbon atoms constituting the aromatic hydrocarbon ring are substituted with a hetero atom. Examples of the hetero atom in the aromatic heterocyclic ring include an oxygen atom, a sulfur atom, and a nitrogen atom. Specific examples of the aromatic heterocyclic ring include a pyridine ring and a thiophene ring.

Specific examples of the aromatic hydrocarbon group in R^{a24} include a group (an aryl group or a heteroaryl group) formed by removing one hydrogen atom from the aromatic hydrocarbon ring or aromatic heterocyclic ring; a group formed by removing one hydrogen atom from an aromatic compound (biphenyl, fluorene, or the like) having two or more aromatic rings; and a group (for example, an arylalkyl group such as a benzyl group, a phenethyl group, a 1-naphthylmethyl group, a 2-naphthylmethyl group, a 1-naphthylethyl group, or a 2-naphthylethyl group) in which one hydrogen atom in an aromatic hydrocarbon ring or aromatic heterocyclic ring is substituted with an alkylene group. The number of carbon atoms of the alkylene group which is bonded to the aromatic hydrocarbon ring or the aromatic heterocyclic ring is preferably in a range of 1 to 4, more preferably 1 or 2, and particularly preferably 1.

In Formulae (anv2) and (anv3), R^{a25} and R^{a26}, and R^{a28} to R^{a30} each independently represent a hydrogen atom, an alkyl group having 1 to 5 carbon atoms, or a halogen atom, and the alkyl group having 1 to 5 carbon atoms and the halogen atom each have the same definition as that for R^{a22} and R^{a23}.

In Formula (anv3), R^{a27} represents an epoxy group-containing group or a hydrocarbon group which may have a substituent. The epoxy group-containing group as R^{a27} has the same definition as that for R^{EP} in Formula (A1), and the hydrocarbon group which may have a substituent as R^{a27} has the same definition as that for R^{a24}.

Specific examples of the constitutional units represented by Formula (anv2) and (anv3) are shown below.

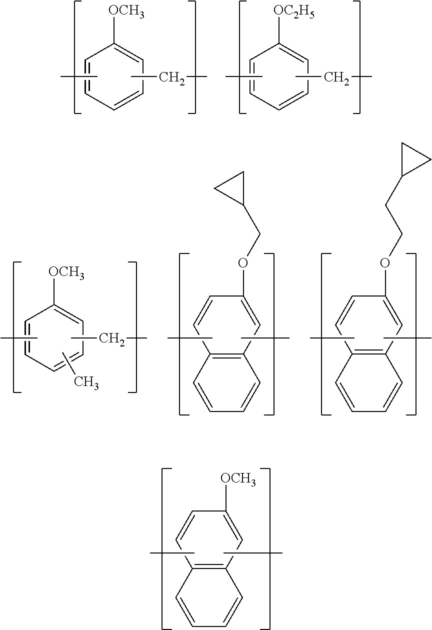

In a case where the novolac epoxy resin (Anv) has other constitutional units in addition to the constitutional unit (anv1), the proportion of each constitutional unit in the resin (Anv) is not particularly limited, but the total amount of the constitutional units containing an epoxy group is preferably in a range of 10 to 90 mol %, more preferably in a range of 20 to 80 mol %, and still more preferably in a range of 30 to 70 mol % with respect to the total amount of all constitutional units constituting the resin (Anv).

<<Bisphenol a Type Epoxy Resin (Abp)>>

Examples of the bisphenol A type epoxy resin (Abp) include an epoxy resin having a structure represented by Formula (abp1).

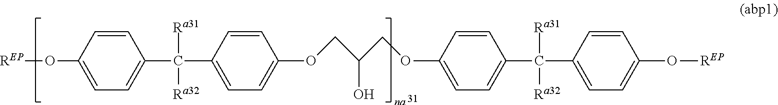

[In Formula, R^{EP} represents an epoxy group-containing group, R^{a31} and R^{a32} each independently represents a hydrogen atom or an alkyl group having 1 to 5 carbon atoms, and na³¹ represents an integer of 1 to 50.]

In Formula (abp1), the alkyl group having 1 to 5 carbon atoms for R^{a31} and R^{a32} has the same definition as that for R^{p1} and R^{p2} in Formula (A1). Among the examples, it is preferable that R^{a31} and R^{a32} represent a hydrogen atom or a methyl group.

R^{EP} has the same definition as that for R^{EP} in Formula (A1), and it is preferable that R^{EP} represents a glycidyl group.

<<Aliphatic Epoxy Resin and Acrylic Resin (Aac)>>

Examples of the aliphatic epoxy resin and the acrylic resin (Aac) include resins having an epoxy group-containing unit represented by Formulae (a1-1) and (a1-2).

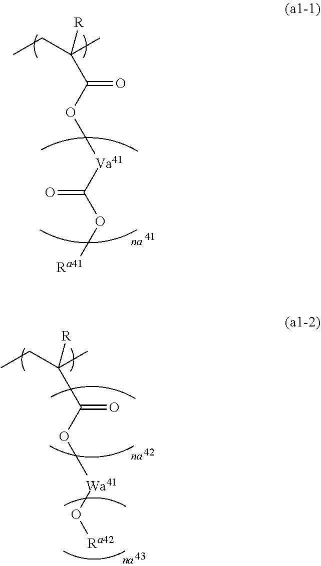

[In Formulae, R represents a hydrogen atom, an alkyl group having 1 to 5 carbon atoms, or a halogenated alkyl group having 1 to 5 carbon atoms. V^{a41} represents a divalent hydrocarbon group which may have a substituent. na⁴¹ represents an integer of 0 to 2. R^{a41} and R^{a42} represent an epoxy group-containing group. na⁴² represents 0 or 1. Wa⁴¹ represents an (na⁴³+1)-valent aliphatic hydrocarbon group. na⁴³ represents an integer of 1 to 3.]

In Formula (a1-1), R represents a hydrogen atom, an alkyl group having 1 to 5 carbon atoms, or a halogenated alkyl group having 1 to 5 carbon atoms.

As the alkyl group having 1 to 5 carbon atoms as R, a linear or branched alkyl group is preferable, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R is a group in which some or all hydrogen atoms in the alkyl group having 1 to 5 carbon atoms are substituted with halogen atoms. Examples of the halogen atom include a fluorine atom, a chlorine atom, a bromine atom, and an iodine atom. Among these, a fluorine atom is particularly preferable.

As R, a hydrogen atom, an alkyl group having 1 to 5 carbon atoms, or a fluorinated alkyl group having 1 to 5 carbon atoms is preferable, and a hydrogen atom or a methyl group is most preferable from the viewpoint of industrial availability.

In Formula (a1-1), Va⁴¹ represents a divalent hydrocarbon group which may have a substituent, and examples thereof are the same as those for the divalent hydrocarbon group which may have a substituent, described in the section of R^{EP} in Formula (A1).

Among these, as the hydrocarbon group represented by Va⁴¹, an aliphatic hydrocarbon group is preferable, a linear or branched aliphatic hydrocarbon group is more preferable, a linear aliphatic hydrocarbon group is still more preferable, and a linear alkylene group is particularly preferable.

In Formula (a1-1), na⁴¹ represents an integer of 0 to 2 and preferably 0 or 1.

In Formulae (a1-1) and (a1-2), R^{a41} and R^{a42} represent an epoxy group-containing group and have the same definition as that for R^{EP} in Formula (A1).

In Formula (a1-2), the (na⁴³+1)-valent aliphatic hydrocarbon group in Wa⁴¹ indicates a hydrocarbon group with no aromaticity, and may be saturated or unsaturated. In general, it is preferable that the aliphatic hydrocarbon group is saturated. Examples of the aliphatic hydrocarbon group include a linear or branched aliphatic hydrocarbon group, an aliphatic hydrocarbon group having a ring in the structure thereof, and a group formed by combining a linear or branched aliphatic hydrocarbon group and an aliphatic hydrocarbon group having a ring in the structure thereof.

In Formula (a1-2), na⁴³ represents an integer of 1 to 3 and preferably 1 or 2.

Specific examples of the constitutional unit represented by Formula (a1-1) or (a1-2) are shown below.

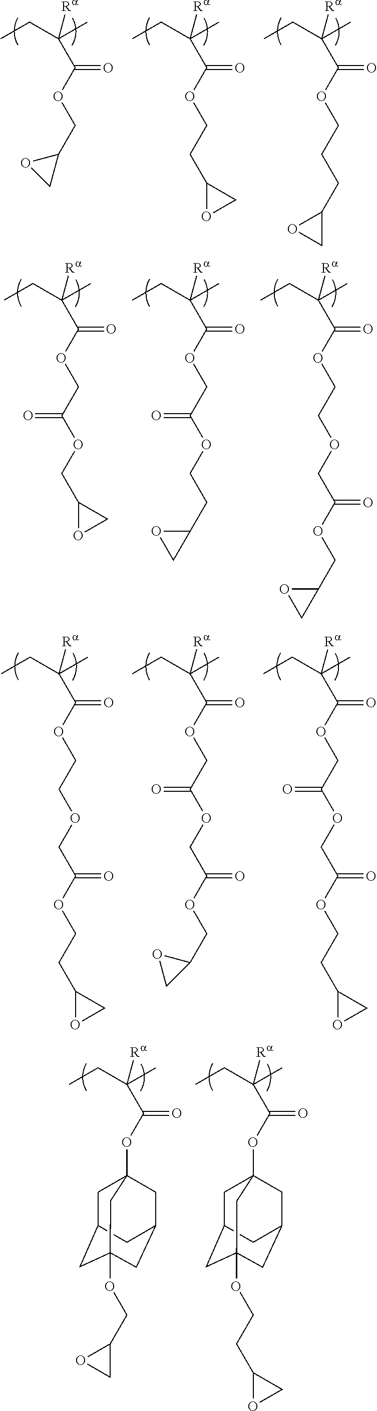

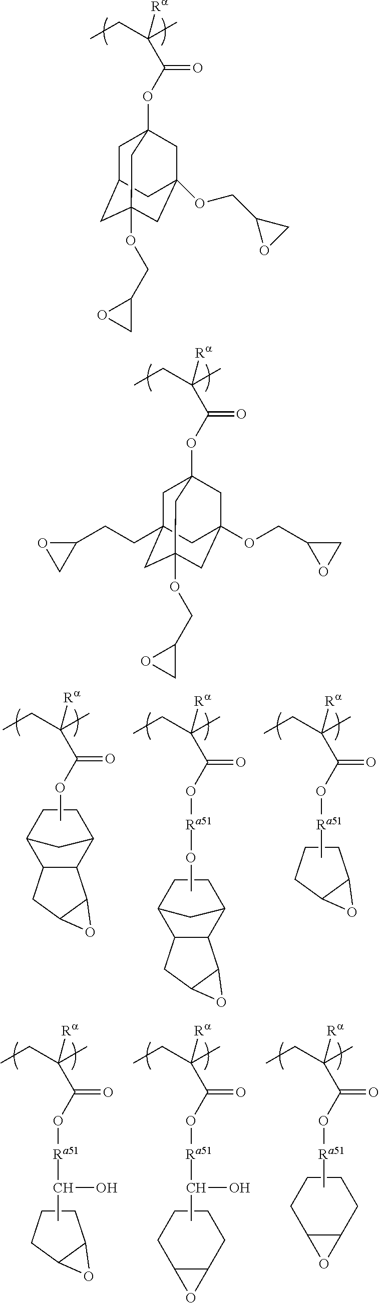

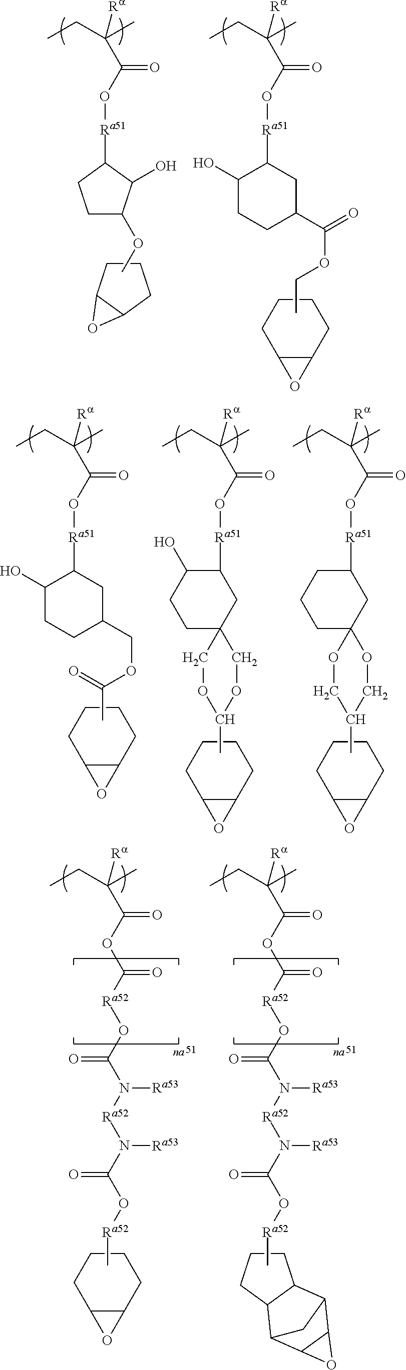

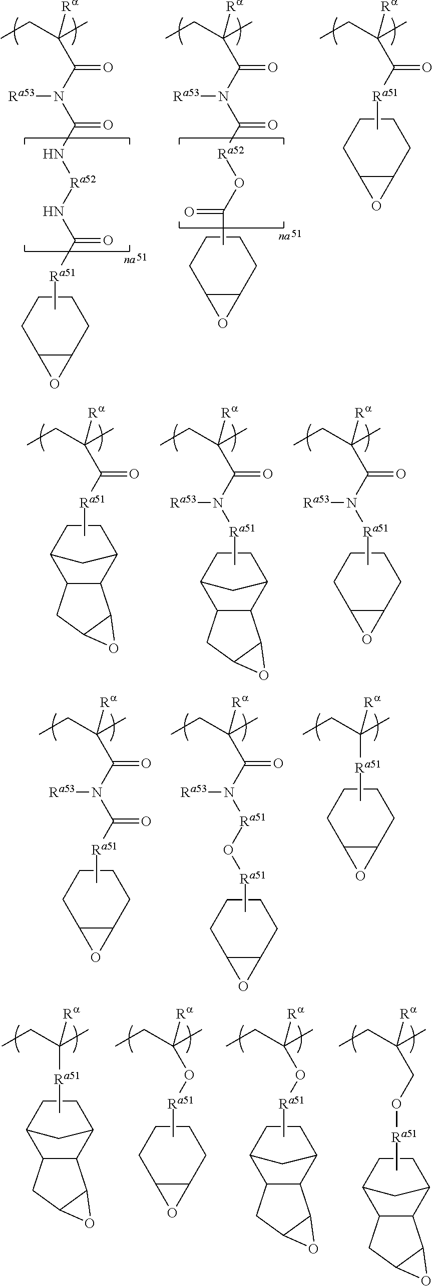

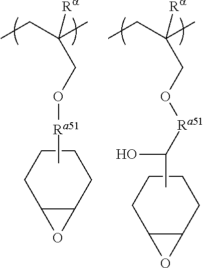

In Formulae, Ra represents a hydrogen atom, a methyl group, or a trifluoromethyl group.

R^{a51} represents a divalent hydrocarbon group having 1 to 8 carbon atoms. R^{a52} represents a divalent hydrocarbon group having 1 to 20 carbon atoms. R^{a53} represents a hydrogen atom or a methyl group. na⁵¹ represents an integer of 0 to 10.

R^{a51}, R^{a52}, and R^{a53} may be the same as or different from one another.

Further, the acrylic resin (Aac) may have a constitutional unit derived from other polymerizable compounds for the purpose of appropriately controlling the physical and chemical characteristics. Examples of such a polymerizable compound include known radical polymerizable compounds and anionic polymerizable compounds. Examples of such a polymerizable compound include monocarboxylic acids such as acrylic acid, methacrylic acid, and crotonic acid; dicarboxylic acids such as maleic acid, fumaric acid, and itaconic acid; methacrylic acid derivatives containing a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl (meth)acrylate, ethyl (meth)acrylate, and butyl (meth)acrylate; (meth)acrylic acid hydroxy alkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene, and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

In a case where the aliphatic epoxy resin and the acrylic resin (Aac) have other constitutional units, the content ratio of the epoxy group-containing unit in the resin is preferably in a range of 1 to 40 mol %, more preferably in a range of 5 to 30 mol %, and most preferably in a range of 5 to 20 mol %.

Further, suitable examples of the aliphatic epoxy resin also include a compound (hereinafter, also referred to as a “component (m1)”) having a partial structure represented by Formula (m1).

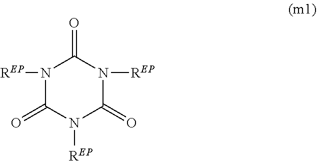

[In Formula, R^{EP} represents an epoxy group-containing group. A plurality of R^{EP}'s may be the same as or different from one another.]

In Formula (m1), R^{EP} represents an epoxy group-containing group and has the same definition as that for R^{EP} in Formula (A1).

The component (A) may be used alone or in combination of two or more kinds thereof.

It is preferable that the component (A) contains at least one resin selected from the group consisting of the novolac epoxy resin (Anv), the bisphenol A type epoxy resin (Abp), a bisphenol F type epoxy resin, the aliphatic epoxy resin, and the acrylic resin (Aac).

Among these, it is more preferable that the component (A) contains at least one resin selected from the group consisting of the novolac epoxy resin (Anv), the bisphenol A type resin (Abp), the aliphatic epoxy resin, and the acrylic resin (Aac).

Among these, it is still more preferable that the component (A) contains at least one resin selected from the group consisting of a novolac epoxy resin (Anv) and an aliphatic epoxy resin.

In a case where the component (A) is used in combination of two or more kinds thereof, it is particularly preferable that the component (A) contains a combination of the novolac epoxy resin (Anv) and the aliphatic epoxy resin.

Specific examples of such a combination include a combination of a component (A1) and at least one (hereinafter, referred to as a “component (m)”) selected from the group consisting of a component (m1).

From the viewpoint of the balance between the hardness and the flexibility of an exposed photosensitive resin film, the mass ratio between the component (A1) and the component (m1) (component (A1)/component (m1)) is preferably in a range of 70/30 to 95/5, more preferably in a range of 80/20 to 95/5, and still more preferably in a range of 85/15 to 95/5.

The weight-average molecular weight of the component (A) in terms of polystyrene is preferably in a range of 100 to 300000, more preferably in a range of 200 to 200000, and still more preferably in a range of 300 to 200000. By setting the weight-average molecular weight to be in the above-described range, the film is unlikely to be peeled off from a support and the hardness of the exposed photosensitive resin film is sufficiently increased.

Further, the dispersity of the component (A) is preferably 1.05 or greater. By setting the dispersity thereof to such a value, lithography characteristics in pattern formation are more improved.

The dispersity here indicates a value obtained by dividing the weight-average molecular weight by the number-average molecular weight.

Examples of commercially available products of the component (A) include, as novolac epoxy resins (Anv), JER-152, JER-154, JER-157S70, and JER-157S65 (all manufactured by Mitsubishi Chemical Corporation), EPICLON N-740, EPICLON N-770, EPICLON N-775, EPICLON N-660, EPICLON N-665, EPICLON N-670, EPICLON N-673, EPICLON N-680, EPICLON N-690, EPICLON N-695, and EPICLON HP5000 (all manufactured by DIC Corporation), and EOCN-1020 (manufactured by Nippon Kayaku Co., Ltd.).

Examples of commercially available products of the component (A) include, as bisphenol A type epoxy resins (Abp), JER-827, JER-828, JER-834, JER-1001, JER-1002, JER-1003, JER-1055, JER-1007, JER-1009, and JER-1010 (all manufactured by Mitsubishi Chemical Corporation), and EPICLON 860, EPICLON 1050, EPICLON 1051, and EPICLON 1055 (all manufactured by DIC Corporation).

Examples of commercially available products of the component (A) include, as bisphenol F type epoxy resins, JER-806, JER-807, JER-4004, JER-4005, JER-4007, and JER-4010 (all manufactured by Mitsubishi Chemical Corporation), EPICLON830 and EPICLON835 (both manufactured by DIC Corporation), and LCE-21 and RE-602S (both manufactured by Nippon Kayaku Co., Ltd.).

Examples of commercially available products of the component (A) include, as aliphatic epoxy resins, ADEKA RESIN EP-4080S, ADEKA RESIN EP-4085S, and ADEKA RESIN EP-4088S (all manufactured by ADEKA CORPORATION), CELLOXIDE 2021P, CELLOXIDE 2081, CELLOXIDE 2083, CELLOXIDE 2085, CELLOXIDE 8000, EHPE-3150, EPOLEAD PB 3600, and EPOLEAD PB4700 (all manufactured by Daicel Corporation), DENACOL EX-211L, EX-212L, EX-214L, EX-216L, EX-321L, and EX-850L (all manufactured by Nagase ChemteX Corporation), and TEPIC-VL (manufactured by Nissan Chemical Industries, Ltd.).

The content of the component (A) in the photosensitive composition according to the present embodiment may be adjusted according to the film thickness and the like of the photosensitive resin film intended to be formed.

<Cationic Polymerization Initiator (I)>

The cationic polymerization initiator (component (I)) is a compound generating a cation by being irradiated with active energy rays such as ultraviolet rays, far ultraviolet rays, excimer laser light of KrF, ArF, and the like, X rays, and electron beams, and the cation becoming a polymerization initiator.

The component (I) in the photosensitive composition according to the present embodiment is not particularly limited, and examples thereof include a compound represented by Formula (I1) (hereinafter, referred to as a “component (I1)”), a compound represented by Formula (I2) (hereinafter, referred to as a “component (I2)”), and a compound represented by Formula (I3-1) or (I3-2) (hereinafter, referred to as a “component (I3)”).

Among these, since relatively strong acids are generated upon exposure from both of the component (I1) and the component (I2), in a case where a pattern is formed using a photosensitive composition that contains the component (I), sufficient sensitivity is obtained so that an excellent pattern is formed.

<<Component (I1)>>

The component (I1) is a compound represented by Formula (I1).

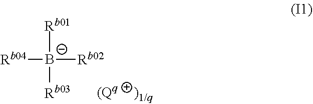

[In Formula, R^{b01} to R^{b04} each independently represent an aryl group which may have a substituent or a fluorine atom. q represents an integer of 1 or greater, and Q^{q+}'s each independently represent a q-valent organic cation.]

Anion Moiety

In Formula (I1), R^{b01} to R^{b04} each independently represent an aryl group which may have a substituent or a fluorine atom.

The aryl group in R^{b01} to R^{b04} has preferably 5 to 30 carbon atoms, more preferably 5 to 20 carbon atoms, still more preferably 6 to 15 carbon atoms, and particularly preferably 6 to 12 carbon atoms. Specific examples thereof include a naphthyl group, a phenyl group, and an anthracenyl group. Among these, a phenyl group is preferable from the viewpoint of availability.

The aryl group in R^{b01} to R^{b04} may have a substituent. The substituent is not particularly limited. As the substituent, a halogen atom, a hydroxyl group, an alkyl group (preferably a linear or branched alkyl group having 1 to 5 carbon atoms), or a halogenated alkyl group is preferable, a halogen atom or a halogenated alkyl group having 1 to 5 carbon atoms is more preferable, and a fluorine atom or a fluorinated alkyl group having 1 to 5 carbon atoms is particularly preferable. It is preferable that the aryl group has a fluorine atom because the polarity of the anion moiety is increased. Among these, R^{b01} to R^{b04} in Formula (I1) each represent preferably a fluorinated phenyl group and particularly preferably a perfluorophenyl group.

Specific preferred examples of the anion moiety of the compound represented by Formula (I1) include tetrakis(pentafluorophenyl)borate ([B(C₆F₅)₄]⁻); tetrakis[(trifluoromethyl)phenyl]borate ([B(C₆H₄CF₃)₄]⁻); difluorobis(pentafluorophenyl)borate ([(C₆F₅)₂BF₂]); trifluoro(pentafluorophenyl)borate ([(C₆F₅)BF₃]⁻); and tetrakis(difluorophenyl)borate ([B(C₆H₃F₂)₄]⁻).

Among these, tetrakis(pentafluorophenyl)borate ([B(C₆F₅)₄]⁻) is particularly preferable.

Cation Moiety

In Formula (I1), q represents an integer of 1 or greater. Q^{q+}'s each independently represent a q-valent organic cation.

Suitable examples of Q^{q+} include a sulfonium cation and an iodonium cation. Further, organic cations represented by Formulae (ca-1) to (ca-5) are particularly preferable.

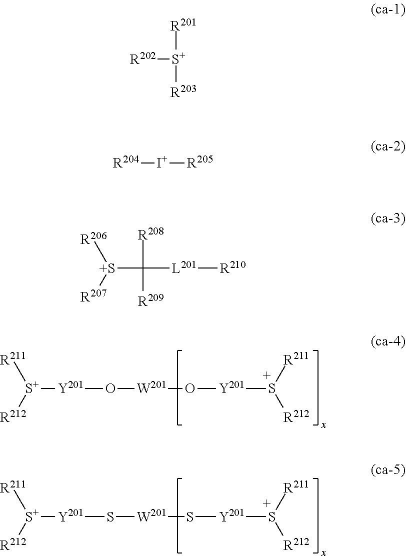

[In Formulae, R²⁰¹ to R²⁰⁷, and R²¹¹ and R²¹² each independently represent an aryl group which may have a substituent, a heteroaryl group, an alkyl group, or an alkenyl group. R²⁰¹ to R²⁰³, R²⁰⁶ and R²⁰⁷, and R²¹¹ and R²¹² may be bonded to one another to form a ring together with a sulfur atom in Formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂-containing cyclic group which may have a substituent. L²⁰¹ represents —C(═O)— or —C(═O)—O—. Y²⁰¹'s each independently represent an arylene group, an alkylene group, or an alkenylene group. x represents 1 or 2. W²⁰¹ represents an (x+1)-valent linking group.]

Examples of the aryl group in R²⁰¹ to R²⁰⁷, and R²¹¹ and R²¹² include an unsubstituted aryl group having 6 to 20 carbon atoms. Among these, a phenyl group or a naphthyl group is preferable.

Examples of the heteroaryl group in R²⁰¹ to R²⁰⁷, and R²¹¹ and R²¹² include those in which some carbon atoms constituting the aryl group are substituted with a hetero atom. Examples of the hetero atom include an oxygen atom, a sulfur atom, and a nitrogen atom. Examples of the heteroaryl group include a group formed by removing one hydrogen atom from 9H-thioxanthene, and examples of the substituted heteroaryl group include a group formed by removing one hydrogen atom from 9H-thioxanthene-9-one.

As the alkyl group in R²⁰¹ to R²⁰⁷, and R²¹¹ and R²¹², a chain-like or cyclic alkyl group having 1 to 30 carbon atoms is preferable.

As the alkenyl group in R²⁰¹ to R²⁰⁷, and R²¹¹ and R²¹², an alkenyl group having 2 to 10 carbon atoms is preferable.

Examples of the substituent which may be included in R²⁰¹ to R²⁰⁷, and R²¹⁰ to R²¹² include an alkyl group, a halogen atom, a halogenated alkyl group, a carbonyl group, a cyano group, an amino group, an oxo group (═O), an aryl group, and groups represented by Formulae (ca-r-1) to (ca-r-10).

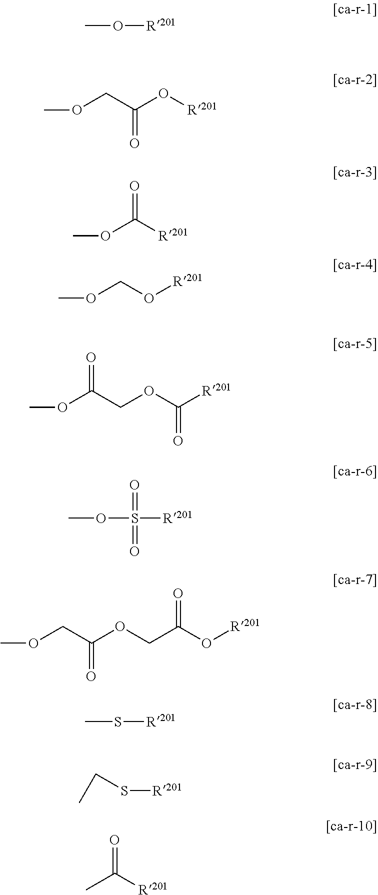

[In Formulae, R′²⁰¹'s each independently represent a hydrogen atom, a cyclic group which may have a substituent, a chain-like alkyl group which may have a substituent, or a chain-like alkenyl group which may have a substituent.]

In Formulae (ca-r-1) to (ca-r-10), R′²⁰¹'s each independently represent a hydrogen atom, a cyclic group which may have a substituent, a chain-like alkyl group which may have a substituent, or a chain-like alkenyl group which may have a substituent.

Cyclic Group which May have Substituent:

It is preferable that the cyclic group is a cyclic hydrocarbon group, and the cyclic hydrocarbon group may be an aromatic hydrocarbon group or a cyclic aliphatic hydrocarbon group. The aliphatic hydrocarbon group indicates a hydrocarbon group with no aromaticity. Further, the aliphatic hydrocarbon group may be saturated or unsaturated. In general, it is preferable that the aliphatic hydrocarbon group is saturated.

The aromatic hydrocarbon group in R′²⁰¹ is a hydrocarbon group having an aromatic ring. The number of carbon atoms of the aromatic hydrocarbon group is preferably in a range of 3 to 30, more preferably in a range of 5 to 30, still more preferably in a range of 5 to 20, particularly preferably in a range of 6 to 15, and most preferably in a range of 6 to 10. Here, the number of carbon atoms thereof does not include the number of carbon atoms in a substituent.

Specific examples of the aromatic ring contained in the aromatic hydrocarbon group in R′²⁰¹ include benzene, fluorene, naphthalene, anthracene, phenanthrene, biphenyl, an aromatic heterocyclic ring in which some carbon atoms constituting any of these aromatic rings are substituted with hetero atom, and a ring in which some hydrogen atoms constituting any of these aromatic rings or aromatic heterocyclic rings are substituted with an oxo group. Examples of the hetero atom in the aromatic heterocyclic ring include an oxygen atom, a sulfur atom, and a nitrogen atom.

Specific examples of the aromatic hydrocarbon group in R′²⁰¹ include a group (an aryl group such as a phenyl group, a naphthyl group, or an anthracenyl group) formed by removing one hydrogen atom from the aromatic ring; a group (an arylalkyl group such as a benzyl group, a phenethyl group, a 1-naphthylmethyl group, a 2-naphthylmethyl group, a 1-naphthylethyl group, or a 2-naphthylethyl group, and the like) in which one hydrogen atom in the aromatic ring is substituted with an alkylene group; a group formed by removing one hydrogen atom from a ring (such as anthraquinone) in which some hydrogen atoms constituting the aromatic ring is substituted with an oxo group and the like; and a group formed by removing one hydrogen atom from an aromatic heterocyclic ring (such as 9H-thioxanthene or 9H-thioxanthen-9-one). The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group in R′²⁰¹ include an aliphatic hydrocarbon group containing a ring in the structure thereof.

Examples of the aliphatic hydrocarbon group containing a ring in the structure thereof include an alicyclic hydrocarbon group (a group formed by removing one hydrogen atom from an aliphatic hydrocarbon ring), a group in which an alicyclic hydrocarbon group is bonded to the terminal of a linear or branched aliphatic hydrocarbon group, and a group in which an alicyclic hydrocarbon group is interposed in a linear or branched aliphatic hydrocarbon group.

The number of carbon atoms in the alicyclic hydrocarbon group is preferably in a range of 3 to 20 and more preferably in a range of 3 to 12.

The alicyclic hydrocarbon group may be a monocyclic group or a polycyclic group. As the monocyclic alicyclic hydrocarbon group, a group formed by removing one or more hydrogen atoms from a monocycloalkane is preferable. The number of carbon atoms of the monocycloalkane is preferably in a range of 3 to 6, and specific examples of such a monocycloalkane include cyclopentane and cyclohexane. As the polycyclic alicyclic hydrocarbon group, a group formed by removing one or more hydrogen atoms from a polycycloalkane is preferable, and the number of carbon atoms of the polycycloalkane is preferably in a range of 7 to 30. Among polycycloalkanes, a polycycloalkane having a bridged ring polycyclic skeleton, such as adamantane, norbomane, isobornane, tricyclodecane, or tetracyclododecane, and a polycycloalkane having a fused ring polycyclic skeleton, such as a cyclic group having a steroid skeleton are more preferable.

Among these examples, as the cyclic aliphatic hydrocarbon group in R′²⁰¹, a group formed by removing one or more hydrogen atoms from a monocycloalkane or a polycycloalkane is preferable, a group formed by removing one hydrogen atom from a polycycloalkane is more preferable, an adamantyl group or a norbomyl group is particularly preferable, and an adamantyl group is most preferable.

The number of carbon atoms of the linear or branched aliphatic hydrocarbon group which may be bonded to the alicyclic hydrocarbon group is preferably in a range of 1 to 10, more preferably in a range of 1 to 6, still more preferably in a range of 1 to 4, and most preferably in a range of 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄-] and a pentamethylene group [—(CH₂)₅—].

As the branched aliphatic hydrocarbon group, a branched alkylene group is preferable. Specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Chain-like alkyl group which may have substituent:

The chain-like alkyl group as R′²⁰¹ may be linear or branched.

The linear alkyl group has preferably 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group.

The branched alkyl group has preferably 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

The chain-like alkenyl group as R′²⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the examples, as the chain-like alkenyl group, a linear alkenyl group is preferable, a vinyl group or a propenyl group is more preferable, and a vinyl group is particularly preferable.

Examples of the substituent in the cyclic group, the chain-like alkyl group, or the chain-like alkenyl group as R′²⁰¹ include an alkoxy group, a halogen atom, a halogenated alkyl group, a hydroxyl group, a carbonyl group, a nitro group, an amino group, an oxo group, the cyclic group in R′²⁰¹, an alkylcarbonyl group, and a thienylcarbonyl group.

Among these, it is preferable that R′²⁰¹ represents a cyclic group which may have a substituent or a chain-like alkyl group which may have a substituent.

In a case where R²⁰¹ to R²⁰³, R²⁰⁶ and R²⁰⁷, and R²¹¹ and R²¹² are bonded to one another to form a ring together with the sulfur atom in the formula, these groups may be bonded to one another through a hetero atom such as a sulfur atom, an oxygen atom, or a nitrogen atom, or a functional group such as a carbonyl group, —SO—, —SO₂—, —SO₃—, —COO—, —CONH—, or —N(R_{N})— (here, R_{N} represents an alkyl group having 1 to 5 carbon atoms). As a ring to be formed, one ring containing the sulfur atom in the formula in the ring skeleton thereof is preferably a 3- to 10-membered ring and particularly preferably a 5- to 7-membered ring, including the sulfur atom. Specific examples of the ring to be formed include a thiophene ring, a thiazole ring, a benzothiophene ring, a thianthrene ring, a benzothiophene ring, a dibenzothiophene ring, a 9H-thioxanthene ring, a thioxanthone ring, a phenoxathiin ring, a tetrahydrothiophenium ring, and a tetrahydrothiopyranium ring.

In Formula (ca-3), R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ each represent an alkyl group, R²⁰⁸ and R²⁰⁹ may be bonded to each other to form a ring.

In Formula (ca-3), R²¹⁰ represents an aryl group which may have a substituent, an alkyl group which may have a substituent, an alkenyl group which may have a substituent, or a —SO₂-containing cyclic group which may have a substituent.

Examples of the aryl group in R²¹⁰ include an unsubstituted aryl group having 6 to 20 carbon atoms, and a phenyl group or a naphthyl group is preferable.

As the alkyl group in R²¹⁰, a chain-like or cyclic alkyl group having 1 to 30 carbon atoms is preferable.

The number of carbon atoms of the alkenyl group in R²¹⁰ is preferably in a range of 2 to 10.

In Formulae (ca-4) and (ca-5), Y²⁰¹'s each independently represent an arylene group, an alkylene group, or an alkenylene group.

Examples of the arylene group in Y²⁰¹ include a group formed by removing one hydrogen atom from an aryl group exemplified as the aromatic hydrocarbon group in R′²⁰¹.

Examples of the alkylene group and alkenylene group in Y²⁰¹ include a group formed by removing one hydrogen atom from a group exemplified as the chain-like alkyl group or the chain-like alkenyl group in R′²⁰¹.

In Formulae (ca-4) and (ca-5), x represents 1 or 2.

W²⁰¹ represents an (x+1)-valent linking group, that is, a divalent or trivalent linking group.

As the divalent linking group in W²⁰¹, a divalent hydrocarbon group which may have a substituent is preferable. Further, the same divalent hydrocarbon groups which may have a substituent exemplified in the section of R^{EP} in Formula (A1) are preferable. The divalent linking group in W²⁰¹ may be linear, branched, or cyclic, and a cyclic divalent linking group is preferable. Among these, a group formed by combining two carbonyl groups at both ends of an arylene group or a group formed of only an arylene group is preferable. Examples of the arylene group include a phenylene group and a naphthylene group. Among these, a phenylene group is particularly preferable.

Examples of the trivalent linking group in W²⁰¹ include a group formed by removing one hydrogen atom from the divalent linking group in W²⁰¹ and a group in which the divalent linking group is bonded to the divalent linking group. As the trivalent linking group in W²⁰¹, a group in which two carbonyl groups are bonded to an arylene group is preferable.

Specific suitable examples of the cation represented by Formula (ca-1) include cations represented by Formulae (ca-1-1) to (ca-1-24).

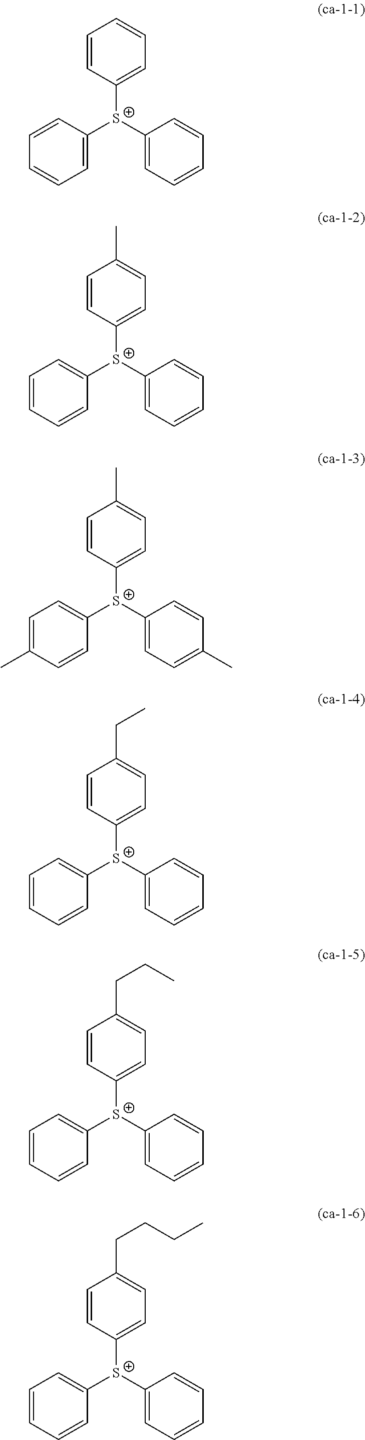

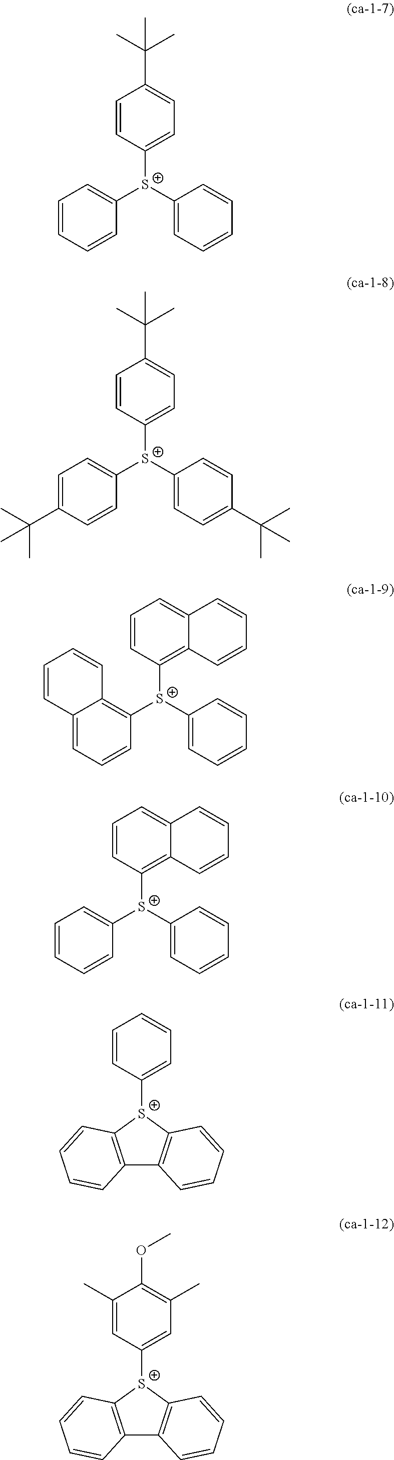 [SMILES: CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; c1ccc([S+](c2cccc3ccccc23)c2cccc3ccccc23)cc1 ; c1ccc([S+](c2ccccc2)c2cccc3ccccc23)cc1 ; c1ccc(-[s+]2c3ccccc3c3ccccc32)cc1 ; COc1c(C)cc(-[s+]2c3ccccc3c3ccccc32)cc1C]

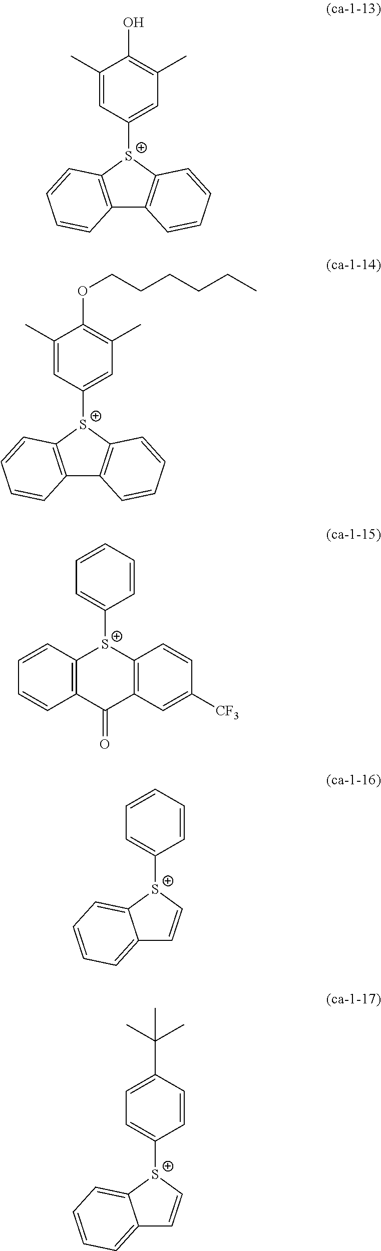 [SMILES: Cc1cc(-[s+]2c3ccccc3c3ccccc32)cc(C)c1O ; CCCCCCOc1c(C)cc(-[s+]2c3ccccc3c3ccccc32)cc1C ; O=c1c2ccccc2[s+](-c2ccccc2)c2ccc(C(F)(F)F)cc12 ; c1ccc(-[s+]2ccc3ccccc32)cc1 ; CC(C)(C)c1ccc(-[s+]2ccc3ccccc32)cc1]

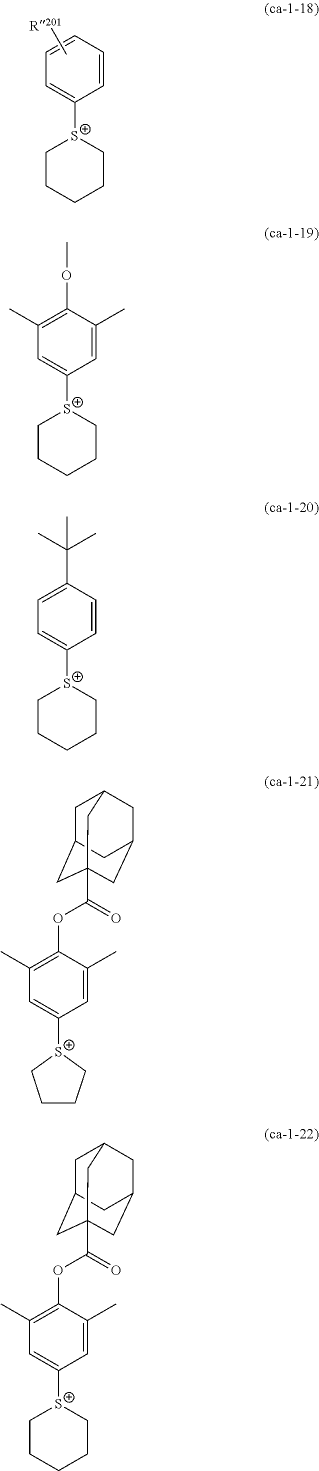

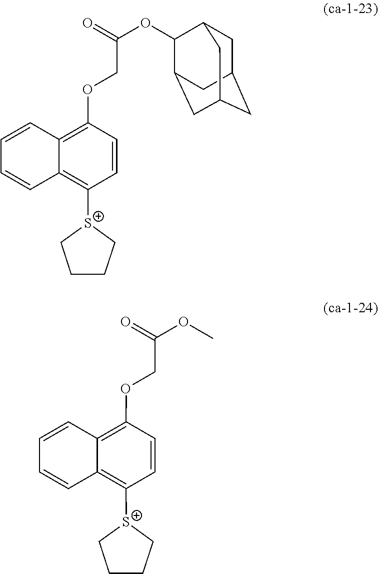 [SMILES: O=C(COc1ccc([S+]2CCCC2)c2ccccc12)OC1C2CC3CC(C2)CC1C3 ; COC(=O)COc1ccc([S+]2CCCC2)c2ccccc12]

[In Formulae, R′²⁰¹ represents a hydrogen atom or a substituent. Examples of the substituent include those exemplified as the substituents which may be included in R²⁰¹ to R²⁰⁷ and R²¹⁰ to R²¹².]

Further, as the cation represented by Formula (ca-1), cations represented by Formulae (ca-1-25) to (ca-1-35) are also preferable.

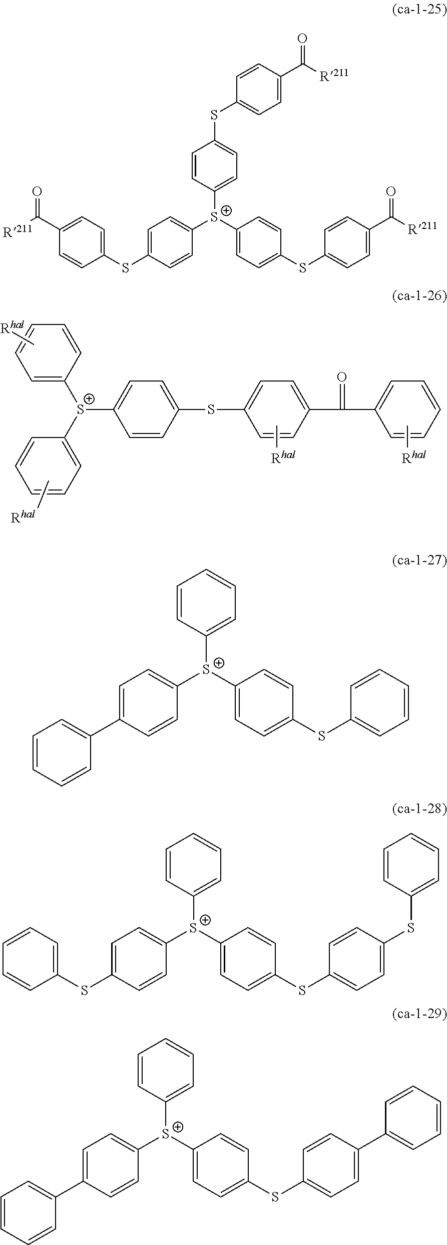

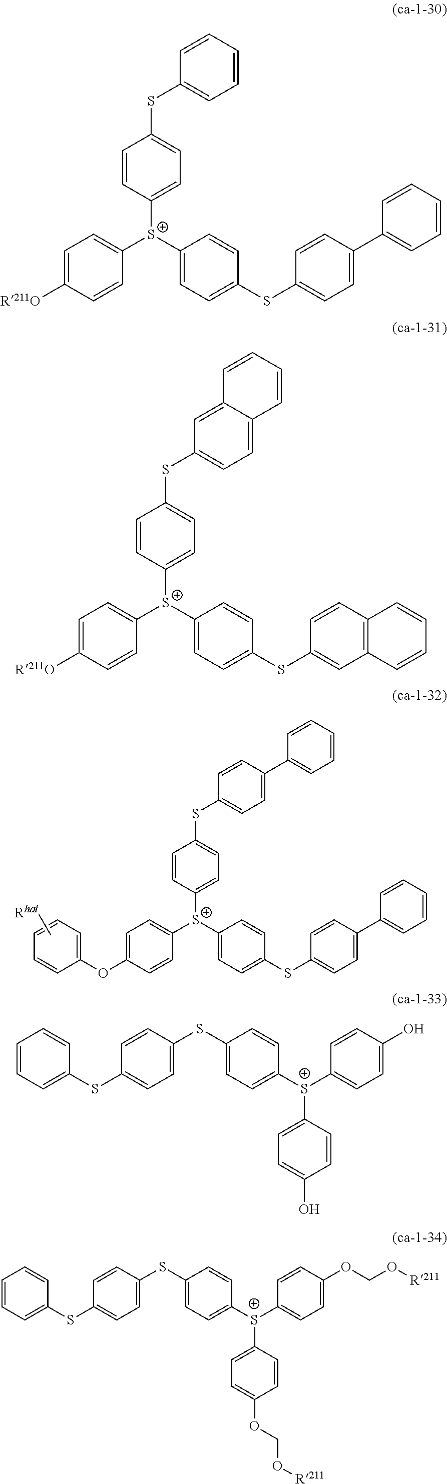

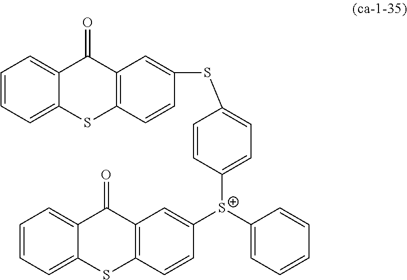 [SMILES: O=c1c2ccccc2sc2ccc(Sc3ccc([S+](c4ccccc4)c4ccc5sc6ccccc6c(=O)c5c4)cc3)cc12]

[In Formulae, R′²¹¹ represents an alkyl group. R^{hal} represents a hydrogen atom or a halogen atom.]

Further, as the cation represented by Formula (ca-1), cations represented by Chemical Formulae (ca-1-36) to (ca-1-46) are also preferable.

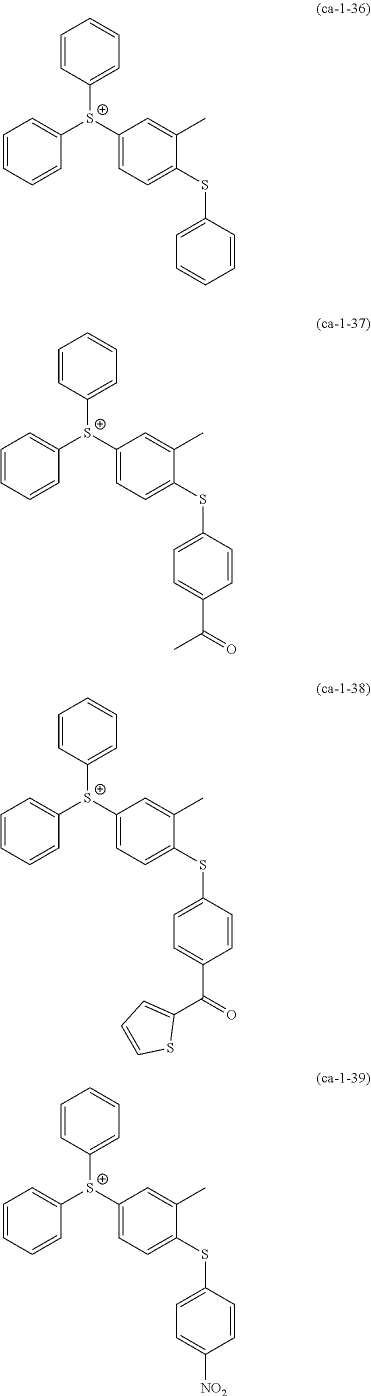 [SMILES: Cc1cc([S+](c2ccccc2)c2ccccc2)ccc1Sc1ccccc1 ; CC(=O)c1ccc(Sc2ccc([S+](c3ccccc3)c3ccccc3)cc2C)cc1 ; Cc1cc([S+](c2ccccc2)c2ccccc2)ccc1Sc1ccc(C(=O)c2cccs2)cc1 ; Cc1cc([S+](c2ccccc2)c2ccccc2)ccc1Sc1ccc([N+](=O)[O-])cc1]

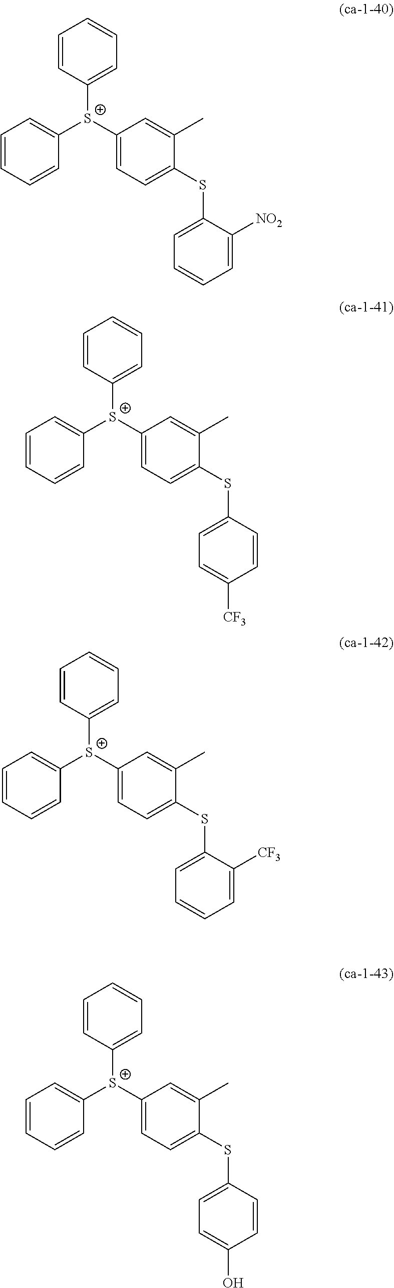 [SMILES: Cc1cc([S+](c2ccccc2)c2ccccc2)ccc1Sc1ccccc1[N+](=O)[O-] ; Cc1cc([S+](c2ccccc2)c2ccccc2)ccc1Sc1ccc(C(F)(F)F)cc1 ; Cc1cc([S+](c2ccccc2)c2ccccc2)ccc1Sc1ccccc1C(F)(F)F ; Cc1cc([S+](c2ccccc2)c2ccccc2)ccc1Sc1ccc(O)cc1]

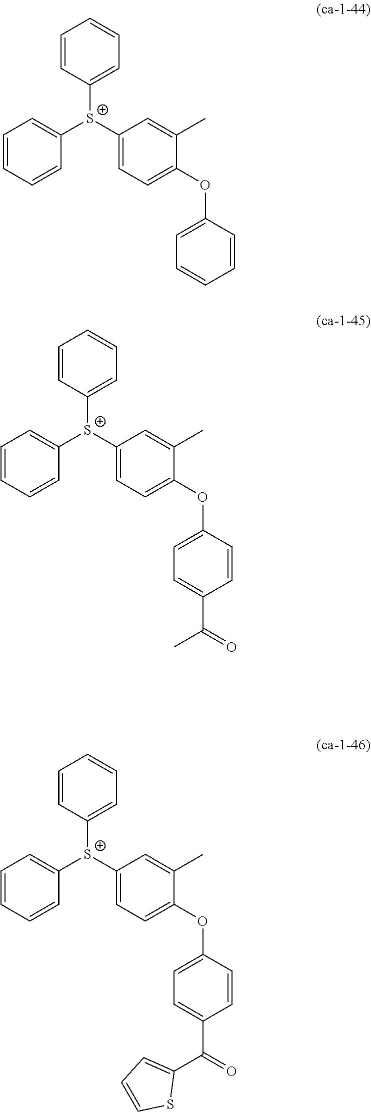 [SMILES: Cc1cc([S+](c2ccccc2)c2ccccc2)ccc1Oc1ccccc1 ; CC(=O)c1ccc(Oc2ccc([S+](c3ccccc3)c3ccccc3)cc2C)cc1 ; Cc1cc([S+](c2ccccc2)c2ccccc2)ccc1Oc1ccc(C(=O)c2cccs2)cc1]

Specific suitable examples of the cation represented by Formula (ca-2) include a diphenyliodonium cation and a bis(4-tert-butylphenyl)iodonium cation.

Specific suitable examples of the cation represented by Formula (ca-4) include cations represented by Formulae (ca-4-1) and (ca-4-2) shown below.

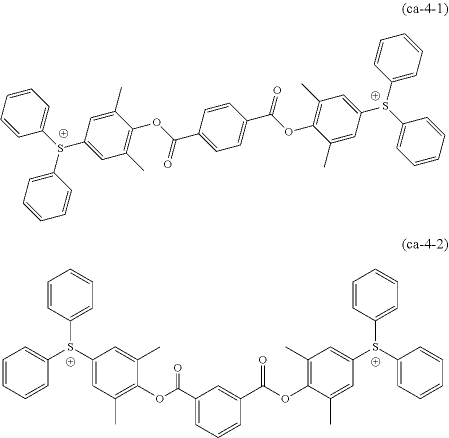 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

As the cation represented by Formula (ca-5), cations represented by Formulae (ca-5-1) to (ca-5-3) are preferable.

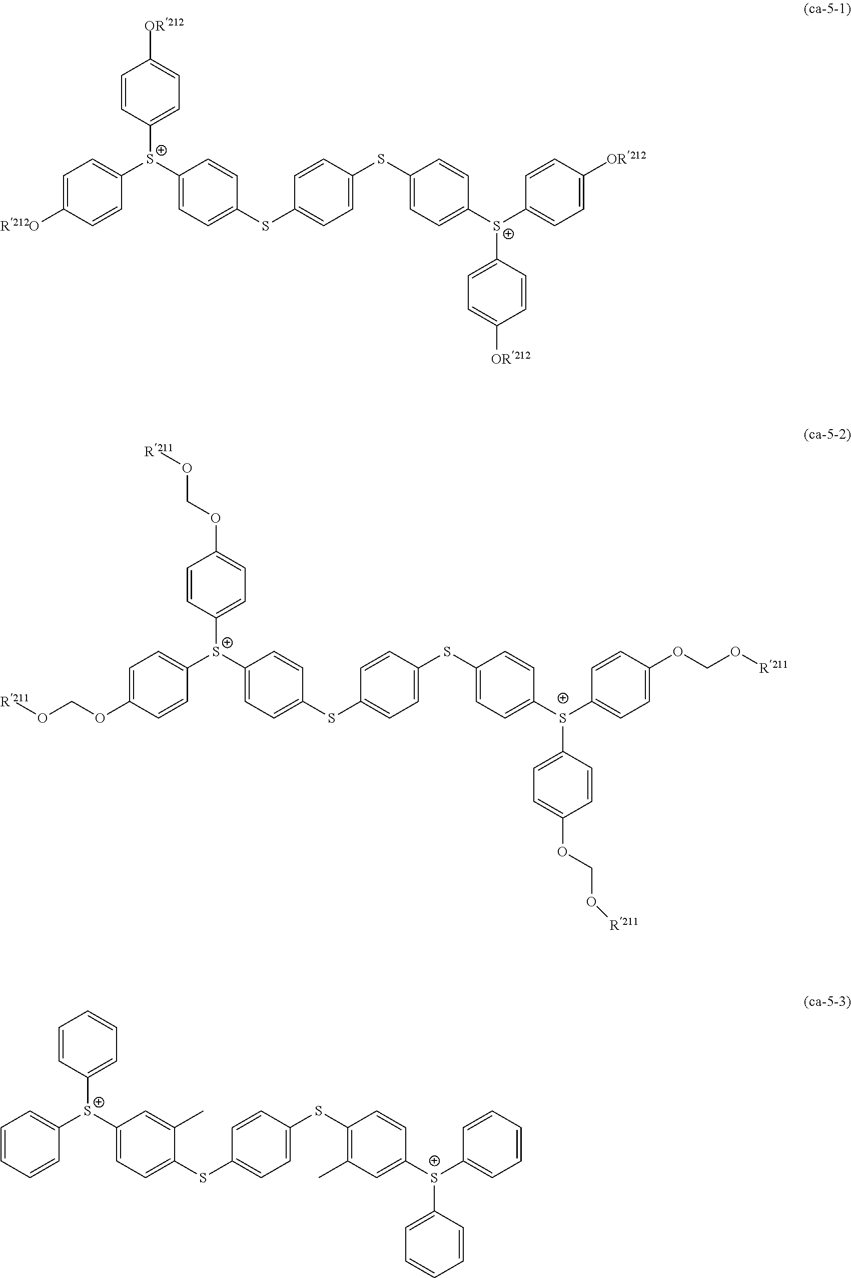

[In Formula, R′²¹² represents an alkyl group or a hydrogen atom. R′²¹¹ represents an alkyl group.]

Among these, as the cation moiety [(Q^{q+})_{1/q}], a cation represented by Formula (ca-1) is preferable, cations represented by Formulae (ca-1-1) to (ca-1-46) are more preferable, and a cation represented by Formula (ca-1-29) is still more preferable.

<<Component (I2)>>

The component (I2) is a compound represented by Formula (I2).

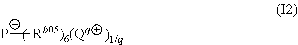

[In Formula, R^{b05} represents a fluorinated alkyl group which may have a substituent or a fluorine atom. A plurality of R^{b05}'s may be the same as or different from one another. q represents an integer of 1 or greater, and Q^{q+}'s each independently represent a q-valent organic cation.]

Anion Moiety

In Formula (I2), R^{b05} represents a fluorinated alkyl group which may have a substituent or a fluorine atom. A plurality of R^{b05}'s may be the same as or different from one another.

The fluorinated alkyl group in R^{b05} has preferably 1 to 10 carbon atoms, more preferably 1 to 8 carbon atoms, and still more preferably 1 to 5 carbon atoms. Specific examples thereof include a group in which some or all hydrogen atoms in an alkyl group having 1 to 5 carbon atoms are substituted with a fluorine atom.

Among the examples, R^{b05} represents preferably a fluorine atom or a fluorinated alkyl group having 1 to 5 carbon atoms more preferably a fluorine atom or a alkyl group having 1 to 5 carbon atoms, more preferably a fluorine atom or a perfluoroalkyl group having 1 to 5 carbon atoms, and still more preferably a fluorine atom, a trifluoromethyl group, or a pentafluoroethyl group.

It is preferable that the anion moiety of the compound represented by Formula (I2) is an anion moiety represented by Formula (b0-2a).

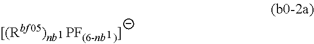

[In Formula, R^{bf05} represents a fluorinated alkyl group which may have a substituent. nb^{I} represents an integer of 1 to 5.]

In Formula (b0-2a), the fluorinated alkyl group which may have a substituent in R^{bf05} has the same definition as the fluorinated alkyl group which may have a substituent, exemplified in R^{b05}.

In Formula (b0-2a), nb¹ represents preferably an integer of 1 to 4, more preferably an integer of 2 to 4, and most preferably 3.

Cation Moiety

In Formula (I2), q represents an integer of 1 or greater and Q^{q+}'s each independently represent a q-valent organic cation.

Examples of Q^{q+} include the same as those described in Formula (I1). Among these, a cation represented by Formula (ca-1) is preferable, cations represented by Formulae (ca-1-1) to (ca-1-46) are more preferable, and a cation represented by Formula (ca-1-35) is still more preferable.

<<Component (I3)>>

The component (I3) is a compound represented by Formula (I3-1) or Formula (I3-2).

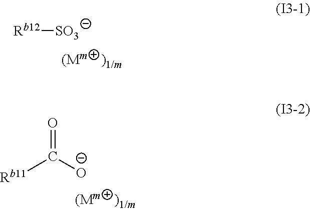

[In Formulae, R^{b11} and R^{b12} represent a cyclic group which may have a substituent other than a halogen atom, a chain-like alkyl group which may have a substituent other than a halogen atom, or a chain-like alkenyl group which may have a substituent other than a halogen atom. m represents an integer of 1 or greater, and M^{m+}'s each independently represent an m-valent organic cation.]

{Component (I3-1)}

Anion Moiety

In Formula (I3-1), R^{b12} represents a cyclic group which may have a substituent other than a halogen atom, a chain-like alkyl group which may have a substituent other than a halogen atom, or a chain-like alkenyl group which may have a substituent other than a halogen atom, and examples thereof include those that do not have a substituent and those having a substituent other than a halogen atom, among the cyclic group, the chain-like alkyl group, and the chain-like alkenyl group in the description for R′²⁰¹ above.

It is preferable that R^{b12} represents a chain-like alkyl group which may have a substituent other than a halogen atom or an aliphatic cyclic group which may have a substituent other than a halogen atom. The number of carbon atoms of the chain-like alkyl group is preferably in a range of 1 to 10 and more preferably in a range of 3 to 10. As the aliphatic cyclic group, a group (which may have a substituent other than a halogen atom) formed by removing one or more hydrogen atoms from adamantane, norbornane, isobornane, tricyclodecane, tetracyclododecane, or the like; or a group formed by removing one or more hydrogen atoms from camphor or the like is more preferable.

The hydrocarbon group as R^{b12} may have a substituent other than a halogen atom. Examples of the substituent include the same as the substituents other than a halogen atom, which may be included in the hydrocarbon group (such as an aromatic hydrocarbon group, an aliphatic cyclic group, or a chain-like alkyl group) in R^{b11} in Formula (I3-2).

The expression “may have a substituent other than a halogen atom” here excludes not only a case of having a substituent formed of only a halogen atom but also a case of having a substituent having even one halogen atom (for example, a case where the substituent is a fluorinated alkyl group).

Specific preferred examples of the anion moiety of the component (I3-1) are shown below.

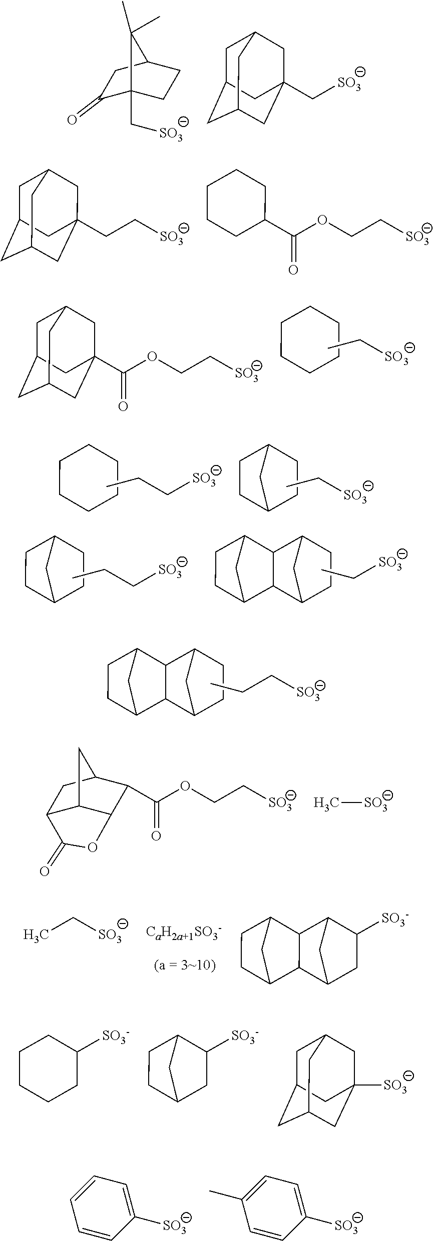

Cation Moiety

In Formula (I3-1), M^{m+} represents an m-valent organic cation.

Suitable examples of the organic cation as M^{m+} are the same as the cations represented by Formulae (ca-1) to (ca-5). Among these, a cation represented by the Formula (ca-1) is more preferable. In addition, a sulfonium cation in which at least one of R²⁰¹, R²⁰², and R²⁰³ in Formula (ca-1) represents an organic group (such as an aryl group, a heteroaryl group, an alkyl group, or an alkenyl group) which may have a substituent and has 16 or more carbon atoms is particularly preferable from the viewpoint of improving resolution and roughness characteristics.

Examples of the substituent which may be included in the organic group include, as described above, an alkyl group, a halogen atom, a halogenated alkyl group, a carbonyl group, a cyano group, an amino group, an oxo group (═O), an aryl group, and groups represented by Formulae (ca-r-1) to (ca-r-10).

The number of carbon atoms of the organic group (such as an aryl group, a heteroaryl group, an alkyl group, or an alkenyl group) is preferably in a range of 16 to 25, more preferably in a range of 16 to 20, and particularly preferably in a range of 16 to 18. Suitable examples of the organic cation as M^{m+} include cations represented by Formulae (ca-1-25), (ca-1-26), (ca-1-28) to (ca-1-36), (ca-1-38), and (ca-1-46). Among these, a cation represented by Formula (ca-1-29) is particularly preferable.

{Component (I3-2)}

Anion Moiety

In Formula (I3-2), R^{b11} represents a cyclic group which may have a substituent other than a halogen atom, a chain-like alkyl group which may have a substituent other than a halogen atom, or a chain-like alkenyl group which may have a substituent other than a halogen atom, and examples thereof include those that do not have a substituent and those having a substituent other than a halogen atom, among the cyclic group, the chain-like alkyl group, and the chain-like alkenyl group in the description for R′²⁰¹ above.

Among these, it is preferable that R^{b11} represents an aromatic hydrocarbon group which may have a substituent other than a halogen atom, an aliphatic cyclic group which may have a substituent other than a halogen atom, and a chain-like alkyl group which may have a substituent other than a halogen atom. Examples of the substituents which may be included in these groups include a hydroxyl group, an oxo group, an alkyl group, an aryl group, a lactone-containing cyclic group, an ether bond, an ester bond, and a combination of these.

In a case where an ether bond or an ester bond is included as the substituent, the substituent may be bonded through an alkylene group, and linking groups represented by Formulae (y-a1-1) to (y-a1-7) are preferable as the substituent in this case.

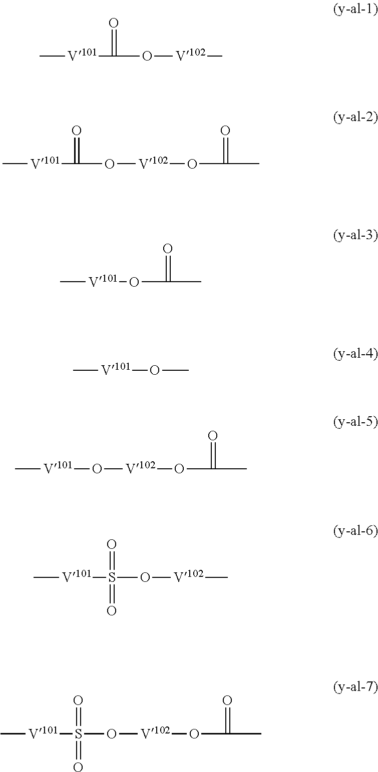

[In Formulae, V′¹⁰¹ represents a single bond or an alkylene group having 1 to 5 carbon atoms, and V′¹⁰² represents a divalent saturated hydrocarbon group having 1 to 30 carbon atoms.]

As the divalent saturated hydrocarbon group in V′¹⁰², an alkylene group having 1 to 30 carbon atoms is preferable, an alkylene group having 1 to 10 carbon atoms is more preferable, and an alkylene group having 1 to 5 carbon atoms is still more preferable.

The alkylene group in V′¹⁰¹ and V′¹⁰² may be a linear alkylene group or a branched alkylene group, and a linear alkylene group is preferable.

Specific examples of the alkylene group in V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

Further, some methylene groups in the alkylene group in V′¹⁰¹ or V′¹⁰² may be substituted with a divalent aliphatic cyclic group having 5 to 10 carbon atoms. As the aliphatic cyclic group, a divalent group formed by further removing one hydrogen atom from a cyclic aliphatic hydrocarbon group as R′²⁰¹ (a monocyclic alicyclic hydrocarbon group or a polycyclic alicyclic hydrocarbon group) is preferable, and a cyclohexylene group, a 1,5-adamantylene group, or a 2,6-adamantylene group is more preferable.

As the aromatic hydrocarbon group, a phenyl group or a naphthyl group is more preferable.

As the aliphatic cyclic group, a group formed by removing one or more hydrogen atoms from a polycycloalkane such as adamantane, norbornane, isobornane, tricyclodecane, or tetracyclododecane is more preferable.

The number of carbon atoms of the chain-like alkyl group is preferably in a range of 1 to 10, and specific examples thereof include a linear alkyl group such as a methyl group, an ethyl group, a propyl group, a butyl group, a pentyl group, a hexyl group, a heptyl group, an octyl group, a nonyl group, or a decyl group; and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

It is preferable that R^{b11} represents a cyclic group which may have a substituent other than a halogen atom.

Specific preferred examples of the anion moiety of the component (I3-2) are shown below.

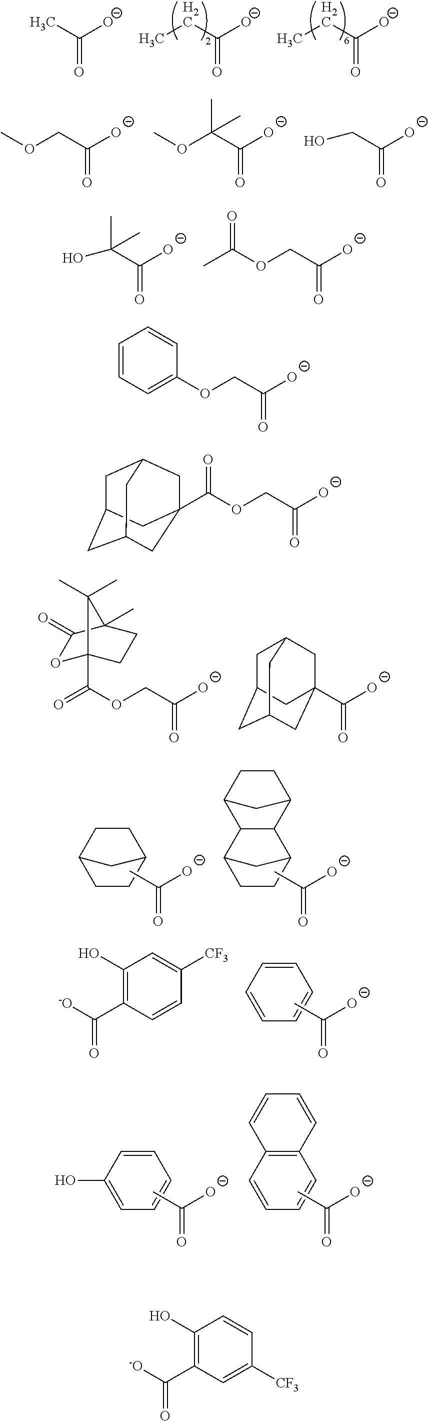

In Formula (I3-2), M^{m+} represents an m-valent organic cation and has the same definition as that for M^{m+} in Formula (I3-1).

From the viewpoints of high elasticity of a resin film and ease of forming a fine structure without residues, it is preferable that the component (I) is a cationic polymerization initiator that generates an acid having a pKa (acid dissociation constant) of −5 or less upon exposure. It becomes possible to obtain high sensitivity upon exposure by using a cationic polymerization initiator that generates an acid having a pKa of more preferably −6 or less and still more preferably −8 or less. The lower limit of the pKa of the acid generated from the component (I) is preferably −15 or greater. The sensitivity is likely to be increased by using a cationic polymerization initiator that generates an acid having a pKa in the above-described suitable range.

Here, “pKa (acid dissociation constant)” is typically used as an index showing the acid strength of a target substance. Further, the pKa in the present specification is a value obtained under a temperature condition of 25° C. Further, the pKa value can be acquired by performing measurement according to a known technique. In addition, calculated values obtained by using a known software such as “ACD/Labs” (trade name, manufactured by Advanced Chemistry Development Inc.) can be used.

Specific suitable examples of the component (I) are shown below.

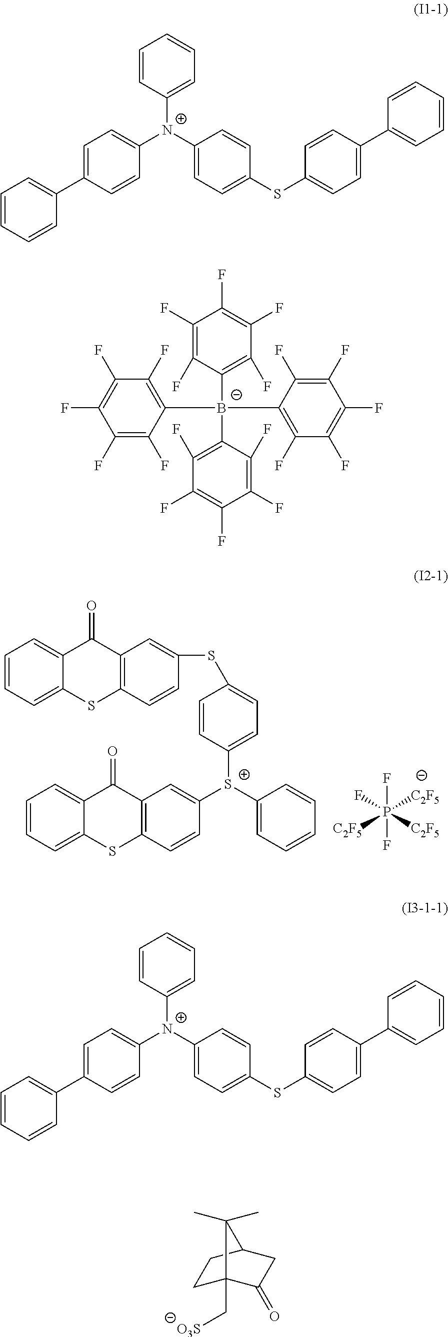

The component (I) may be used alone or in combination of two or more kinds thereof.

The content of the component (I) is preferably in a range of 0.1 to 6.0 parts by mass, more preferably in a range of 0.3 to 4.0 parts by mass, and still more preferably in a range of 0.5 to 3.0 parts by mass with respect to 100 parts by mass of the component (A).

In a case where the content of the component (I) is greater than or equal to the lower limit of the above-described preferable range, sufficient sensitivity is obtained, and lithography characteristics of the pattern are further improved. In addition, the hardness of the exposed photosensitive resin film is further increased. Further, in a case where the content of the component (I) is lower than or equal to the upper limit of the above-described preferable range, the sensitivity is appropriately controlled, and a pattern having an excellent shape is easily obtained.

<Polyfunctional Thiol Compound (T)>

The polyfunctional thiol compound indicates a compound having two or more thiol groups (mercapto group) in a molecule.

The photosensitive composition according to the present embodiment contains the component (T), thereby further improving adhesion properties to a surface of a support (in particular, metal substrate such as Cu, Au, and Cr). In addition, by combining the component (A) and the component (I), it is possible to reliably form a finer pattern.

The component (T) may be a polyfunctional aliphatic thiol compound, or may be a polyfunctional aromatic thiol compound.

The number of thiol groups contained in the component (T) is preferably 2 to 8 and more preferably 2 to 4.

Examples of the polyfunctional thiol compound having two thiol groups include ethanedithiol, 1,2-propanedithiol, 1,3-propanedithiol, 1,4-butanedithiol, 1,5-pentanedithiol, 1,6-hexanedithiol, 1,9-nonanedithiol, 1,10-decanedithiol, 3,6-dioxa-1,8-octanedithiol, ethylene glycol bisthioglycolate, bis(2-mercaptoethyl)ether, 1,4-bis(3-mercaptobutyloxy)butane, bis(2-mercaptoethyl)sulfide, and 1,4-bis(mercaptomethyl)benzene.

Examples of the polyfunctional thiol compound having three thiol groups include 2-[(mercaptoacetyloxy)methyl]-2-ethyl-1,3-propanediol bis(mercaptoacetate), trimethyloyl propane tris(3-mercaptopropionate), trimethylol propane tris(3-mercapto butylate), trimethylol ethane tris(3-mercaptobutylate), tris[(3-mercaptopropionyloxy)-ethyl]-isocyanurate, 1,3,5-tris(3-mercaptobutyloxyethyl)-1,3,5-triazine-2,4,6(1H,3H,5H)-trione, 1,3,5-benzene trithiol, 1,3,5-tris(mercaptomethyl)benzene, and 1,3,5-triazine-2,4,6-trithiol.

Examples of the polyfunctional thiol compound having four thiol groups include pentaerythritol tetrakis(3-mercaptopropionate), and pentaerythritol tetrakis(3-mercaptobutyrate).

Among these, the component (T) in the photosensitive composition according to the present embodiment preferably has a divalent linking group including an oxygen atom, from the viewpoint of compatibility with the component (A). Examples of the preferable linking group include —O—, —C(═O)—, —C(═O)—O—, and —C(═O)—NR^{T}—C(═O)— (R^{T} is a divalent linking group, the same group as the divalent linking group in R^{EP} in Formula (A1) is exemplified).

From the viewpoint of compatibility with the component (A), the component (T) is preferably a low-molecular compound having a molecular weight of 100 to 1500, more preferably a low-molecular compound having a molecular weight of 150 to 1000, and still more preferably a low-molecular compound having a molecular weight of 200 to 800.

From the viewpoints of compatibility with the component (A) and adhesion properties to the support, as the component (T), (molecular weight of polyfunctional thiol compound)/(number of thiol group) is preferably 50 to 1000, more preferably 50 to 500, and still more preferably 100 to 400.

Among these, the component (T) is preferably a compound represented by Formula (T1).

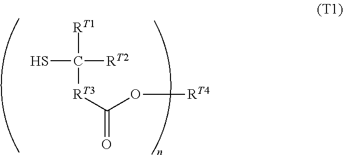

[In Formula, R^{T1} and R^{T2} each independently represent a hydrogen atom or an alkyl group having 1 to 5 carbon atoms. R^{T3} represents a single bond or an alkylene group having 1 to 5 carbon atoms. R^{T4} represents an n-valent hydrocarbon group. n represents an integer of 2 to 4.]

In Formula (T1), R^{T1} and R^{T2} each independently represent a hydrogen atom or an alkyl group having 1 to 5 carbon atoms. It is preferable that one of R^{T1} and R^{T2} is a hydrogen atom and the other is an alkyl group having 1 to 5 carbon atoms. As the alkyl group having 1 to 5 carbon atoms, a methyl group is preferable.

R^{T3} represents a single bond or an alkylene group having 1 to 5 carbon atoms, and is preferably an alkylene group having 1 to 5 carbon atoms and more preferably a methylene group.

R^{T4} represents an n-valent hydrocarbon group. That is, R^{T4} represents a divalent, trivalent, or tetravalent hydrocarbon group. The hydrocarbon group may be an aliphatic hydrocarbon group, may be an aromatic hydrocarbon group, may be a cyclic hydrocarbon group, or may be a chain-like hydrocarbon group.

In addition, the hydrocarbon group may include a hetero atom.

As the divalent hydrocarbon group in R^{T4}, a linear or branched aliphatic hydrocarbon group is preferable, a linear alkylene group is more preferable, and a linear alkylene group having 1 to 5 carbon atoms is still more preferable.

As the trivalent hydrocarbon group in R^{T4}, a trivalent hydrocarbon group including a hetero atom is preferable, and specifically, a group obtained by removing hydrogen atoms (three hydrogen atoms) from each nitrogen atom of 1,3,5-triazine-2,4,6-trione is preferable.

As the tetravalent hydrocarbon group in R^{T4}, a linear or branched aliphatic hydrocarbon group is preferable, and a branched aliphatic hydrocarbon group having 3 to 5 carbon atoms is more preferable.

As a preferable specific example of the component (T) in the photosensitive composition according to the present embodiment, compounds represented by Formulae (T1-1), (T1-2), and (T1-3), respectively, are exemplified. That is, it is preferable that the composition contains one or more compounds selected from the group consisting of (T1-1): pentaerythritol tetrakis(3-mercaptobutyrate), (T1-2): 1,4-bis(3-mercaptobutyloxy)butane, and (T1-3): 1,3,5-tris(3-mercaptobutyloxyethyl)-1,3,5-triazine-2,4,6(1H,3H,5H)-trione.

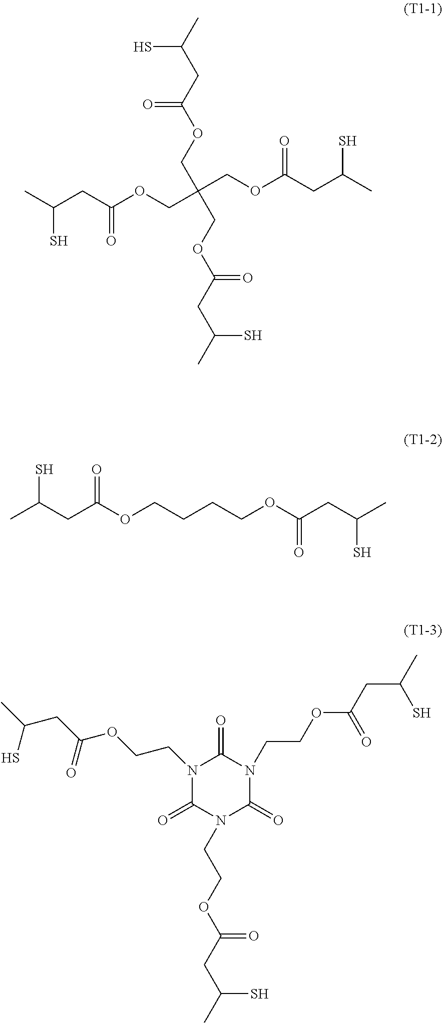

The component (T) may be used alone or in combination of two or more kinds thereof.

The content of the component (T) is preferably in a range of 0.01 to 5 parts by mass, more preferably in a range of 0.05 to 3 parts by mass, and still more preferably in a range of 0.1 to 2 parts by mass with respect to 100 parts by mass of the component (A).

In a case where the content of the component (T) is greater than or equal to the lower limit of the above-described preferable range, adhesion properties to the support are sufficiently obtained. Further, in a case where the content of the component (T) is lower than or equal to the upper limit of the above-described preferable range, reactivity with the component (A) is good, and a finer pattern is easily formed.

<Other Components>

The photosensitive composition according to the present embodiment may contain other components as necessary, in addition to the component (A), the component (I), and the component (T).

Examples of the other components include a metal oxide (M) (hereinafter, referred to as a component (M)), a silane coupling agent (C) (hereinafter, referred to as a component (C)), a solvent (S) (hereinafter, referred to as a component (S)), and a sensitizer component.

<<Metal Oxide (M)>>

The photosensitive composition according to the present embodiment may further contain a metal oxide (M) in order to further improve hardness of the exposed photosensitive resin film.

Examples of the component (M) include oxides of metals such as silicon (metallic silicon), titanium, zirconium, and hafnium. Among these, an oxide of silicon is preferable. In addition, it is particularly preferable to use silica.

Further, it is preferable that the component (M) is particulate.

Such a particulate component (M) is formed of preferably a group consisting of particles having a volume average particle diameter of 5 to 40 nm, more preferably a group consisting of particles having a volume average particle diameter of 5 to 30 nm, and still more preferably a group consisting of particles having a volume average particle diameter of 10 to 20 nm.

In a case where the volume average particle diameter of the component (M) is greater than or equal to the lower limit of the above-described preferable range, the hardness of the exposed photosensitive resin film is likely to be increased. Further, in a case where the volume average particle diameter thereof is lower than or equal to the upper limit of the above-described preferable range, residues are unlikely to be generated during pattern formation, and a pattern with higher resolution is easily formed. In addition, the transparency of the resin film is improved.

The particle diameter of the component (M) may be appropriately selected according to the exposure light source. Typically, it is considered that particles having a particle diameter of 1/10 or less with respect to the wavelength of light are almost not affected by light scattering. Therefore, for example, in a case where a fine structure is formed by photolithography with an i-rays (365 nm), it is preferable that a group (particularly preferably a group of silica particles) consisting of particles having a primary particle diameter (volume average value) of 10 to 20 nm is used as the component (M).

The component (M) may be used alone or in combination of two or more kinds thereof.

The content of the component (M) is preferably in a range of 10 to 30 parts by mass and more preferably in a range of 15 to 25 parts by mass with respect to 100 parts by mass of the component (A).

In a case where the content of the component (M) is greater than or equal to the lower limit of the above-described preferable range, the hardness of the exposed photosensitive resin film is likely to be increased. Further, in a case where the content thereof is lower than or equal to the upper limit of the above-described preferable range, the transparency of the resin film can be further improved. In addition, the fluidity of the photosensitive composition is likely to be maintained.

<<Silane Coupling Agent (C)>>

In addition, the photosensitive composition according to the embodiment may further contain a silane coupling agent (C) in order to further improve adhesion properties to the support.

Examples of the component (C) include silane coupling agents having reactive substituents such as a carboxyl group, a methacryloyl group, an isocyanate group, and an epoxy group. Specific examples thereof include trimethoxysilylbenzoic acid, γ-methacryloxypropyltrimethoxysilane, vinyltriacetoxysilane, vinyltrimethoxysilane, γ-glycidoxypropyltrimethoxysilane, and I3-(3,4-epoxycyclohexyl)ethyltrimethoxysilane.

The component (C) may be used alone or in combination of two or more kinds thereof. The content of the component (C) is preferably in a range of 1 to 20 parts by mass, more preferably in a range of 2 to 15 parts by mass, and still more preferably in a range of 2.5 to 10 parts by mass with respect to 100 parts by mass of the component (A).

In a case where the content of the component (C) is within the above-described preferable range, the hardness of the exposed photosensitive resin film is likely to be increased. In addition, adhesion properties to the support are further improved.

<<Solvent (S)>>

The photosensitive composition according to the embodiment can be produced by dissolving or dispersing a photosensitive material in a solvent (S).

Examples of the component (S) include lactones such as γ-butyrolactone; ketones such as acetone, methyl ethyl ketone (MEK), cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monoethylether, monopropylether, or monobutylether or monophenylether of any of the polyhydric alcohols or the compounds having an ester bond [among these, propylene glycol monomethyl ether acetate (PGMEA), and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and dimethylsulfoxide (DMSO).

The component (S) may be used alone or in the form of a mixed solvent of two or more kinds thereof.

The amount of the component (S) to be used is not particularly limited and is appropriately set so as to have a concentration suitable for application to a substrate or the like depending on the thickness of a coating film.

The content of the component (S) in the photosensitive composition is preferably in a range of 1% to 40% by mass and more preferably in a range of 10% to 35% by mass with respect to the total amount (100% by mass) of the photosensitive composition.

The photosensitive composition according to the embodiment may contain components other than the above-described components. For example, it is possible to appropriately contain an additive resin for improving film performance, a dissolution inhibitor, a basic compound, a plasticizer, a stabilizer, a colorant, a halation-preventing agent, and the like.

The negative-tone photosensitive resin composition according to the present embodiment described above contains the polyfunctional thiol compound (T), in addition to the epoxy group-containing resin (A) and the cationic polymerization initiator (I). Since the component (T) has a plurality of thiol groups, it is possible to improve adhesion properties to any of the surface of the support (in particular, metal substrate such as Cu, Au, and Cr) and the component (A). In addition, it is possible to reliably form a finer pattern by combining the component (I), the component (A), and the component (T).

Therefore, according to the photosensitive composition according to the present embodiment, it is assumed that it is possible to improve adhesion properties to the surface of the support (in particular, metal substrate such as Cu, Au, and Cr) and to form a fine pattern.

(Photosensitive Resist Film)

A photosensitive resist film according to the present embodiment is obtained by laminating a base film, a photosensitive resin film formed by using the negative-tone photosensitive resin composition according to the embodiment described above, and a cover film in this order.

The photosensitive resist film according to the embodiment can be produced, for example, by coating a base film with the negative-tone photosensitive resin composition according to the embodiment described above, drying the composition to form a photosensitive resin film, and laminating a cover film on the photosensitive resin film.

The base film may be coated with the negative-tone photosensitive resin composition according to an appropriate method using a blade coater, a lip coater, a comma coater, or a film coater.

The thickness of the photosensitive resin film is preferably 100 μm or less and more preferably in a range of 5 to 50 μm.

As the base film, known films such as a thermoplastic resin film are used. Examples of the thermoplastic resin include polyesters such as polyethylene terephthalate. The thickness of the base film is preferably in a range of 2 to 150 μm.

As the cover film, known films such as a polyethylene film and a polypropylene film are used. As the cover film, a film of which adhesive force to the photosensitive resin film is smaller than that of the base film is preferable. The thickness of the cover film is preferably in a range of 2 to 150 μm, more preferably in a range of 2 to 100 μm, and still more preferably in a range of 5 to 50 μm.

The base film and the cover film may be formed of the same film material or may be different films.

(Method of Forming Pattern)

A method of forming pattern according to the present embodiment includes a step of forming a photosensitive resin film on a support (hereinafter, referred to as a “film formation step”) using the negative-tone photosensitive resin composition or the photosensitive resist film according to the embodiment described above; a step of exposing the photosensitive resin film (hereinafter, referred to as an “exposure step”); and a step of developing the exposed photosensitive resin film to form a negative-tone pattern (hereinafter, referred to as a “development step”).

For example, the method of forming pattern according to the present embodiment can be performed in the following manner.

[Film Formation Step]

First, a photosensitive resin film is formed by coating a support with the negative-tone photosensitive resin composition according to the embodiment using known methods such as a spin coating method, a roll coating method, or a screen printing method and by performing a bake (post apply bake (PAB)) treatment under a temperature condition of, for example, 50° C. to 150° C. for 2 to 60 minutes.

In the film formation step, a photosensitive resin film may be formed on a support by attaching the photosensitive resist film onto the support. During the attachment, the support or the film may be heated or pressed (laminated) as necessary.

The support is not particularly limited and a known support in the related art can be used. Examples of the support include substrates for electronic components, and such substrates having a predetermined wiring pattern formed thereon. More specific examples thereof include a substrate made of metal such as silicon wafer, copper, chromium, gold, iron, or aluminum; a glass substrate; and a resin film such as polyethylene terephthalate, polyethylene naphthalate, polypropylene, or polyethylene. As the materials for the wiring pattern, copper, aluminum, nickel, and gold can be used.

Further, as the support, any one of the above-described substrates provided with an inorganic and/or organic film may be used. Examples of the inorganic film include an inorganic bottom anti-reflective coating (inorganic BARC). Examples of the organic film include organic films such as an organic bottom anti-reflective coating (organic BARC) and a lower layer organic film according to a multilayer resist method.

Among these, from the viewpoint that the support in the method of forming pattern according to the present embodiment can further improve adhesion properties, the method is useful in a case of using a substrate made of metal such as a silicon wafer, copper, chromium, gold, iron, or aluminum, in particular, a substrate made of copper.

The film thickness of the photosensitive resin film to be formed using the negative-tone photosensitive resin composition or the photosensitive resist film is not particularly limited, but is preferably in a range of approximately 10 to 100 μm. Even in a case where a thick film is formed using the negative-tone photosensitive resin composition according to the embodiment, excellent characteristics are obtained.

[Exposure Step]

Next, the formed photosensitive resin film is exposed through a mask having a predetermined pattern (mask pattern) formed thereon using a known exposure device or selectively exposed through drawing or the like by performing direct irradiation with electron beams without using a mask pattern therebetween. In addition, a bake (post exposure bake (PEB)) treatment is performed as necessary under a temperature condition of 80° C. to 150° C. for 40 to 600 seconds, preferably 60 to 300 seconds.

The wavelength used in the exposure is not particularly limited, and the exposure is performed by selectively radiating (exposing) radiation, for example, ultraviolet rays having a wavelength of 300 to 500 nm, i-rays (wavelength of 365 nm), or visible light rays. As these radiation sources, a low pressure mercury lamp, a high pressure mercury lamp, an ultra-high pressure mercury lamp, a metal halide lamp, and an argon gas laser can be used.

Here, the radiation indicates ultraviolet rays, visible light rays, far ultraviolet rays, X rays, electron beams, or the like. The radiation dose varies depending on the type of each component in the composition, the blending amount thereof, the film thickness of the coating film, and the like. For example, in a case where an ultra-high pressure mercury lamp is used, the radiation does thereof is in a range of 100 to 2000 mJ/cm².

The photosensitive resin film may be exposed through typical exposure (dry exposure) performed in air or an inert gas such as nitrogen or through liquid immersion exposure (liquid immersion lithography).

The photosensitive resin film after the exposure step is highly transparent, and the haze value at the time of irradiation with i-rays (wavelength of 365 nm) is preferably 3% or less and more preferably in a range of 1.0% to 2.7%.

As described above, the photosensitive resin film formed using the negative-tone photosensitive resin composition or the photosensitive resist film according to the embodiment is highly transparent. Therefore, the light transmittance is increased during the exposure in pattern formation so that a negative-tone pattern with excellent lithography characteristics is likely to be obtained.

The haze value of the photosensitive resin film after the exposure step is measured using a method in conformity with JIS K 7136 (2000).

[Development Step]

Next, the exposed photosensitive resin film is subjected to a development treatment. After the development treatment, it is preferable that a rinse treatment is performed. As necessary, a bake treatment (post bake) may be performed.

By performing the above-described film formation step, exposure step, and development step, a pattern can be formed.

The developing solution used in the development treatment may be an alkali aqueous solution or an organic developing solution containing an organic solvent.

As the alkali developing solution, a 0.1 to 10% by mass of tetramethylammonium hydroxide (TMAH) aqueous solution can be exemplified.

As the organic solvent contained in the organic developing solution, a solvent which is capable of dissolving the component (A) (component (A) before the exposure) may be used and can be appropriately selected from known organic solvents. Specific examples of the organic solvent include polar solvents such as ketone solvents, ester solvents, alcohol solvents, nitrile solvents, amide solvents, and ether solvents; and hydrocarbon solvents.

Examples of the ketone solvents include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylenecarbonate, γ-butyrolactone and methyl amyl ketone (2-heptanone). Among these examples, as the ketone solvents, methyl amyl ketone (2-heptanone) is preferable.

Examples of the ester solvents include methyl acetate, butyl acetate, ethyl acetate, isopropyl acetate, amyl acetate, isoamyl acetate, ethyl methoxyacetate, ethyl ethoxyacetate, propylene glycol monomethyl ether acetate (PGMEA), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these examples, as the ester solvents, butyl acetate or PGMEA is preferable.

Examples of the nitrile solvents include acetonitrile, propionitrile, valeronitrile, and butyronitrile.

Known additives can be blended with the organic developing solution as necessary. Examples of the additive include a surfactant. The surfactant is not particularly limited, and for example, an ionic or non-ionic fluorine-based and/or silicon-based surfactant can be used.

As the surfactant, a non-ionic surfactant is preferable, and a non-ionic fluorine-based surfactant or a non-ionic silicon-based surfactant is more preferable.

In a case where a surfactant is blended, the blending amount thereof is typically in a range of 0.001% to 5% by mass, preferably in a range of 0.005% to 2% by mass, and more preferably in a range of 0.01% to 0.5% by mass with respect to the total amount of the organic developing solution.

The development treatment can be performed by a known developing method. Examples thereof include a method of immersing a support in a developing solution for a predetermined time (a dip method), a method of stacking up a developing solution on the surface of a support using the surface tension and maintaining the state for a predetermined time (a puddle method), a method of spraying a developing solution to the surface of a support (a spray method), and a method of continuously ejecting a developing solution from a developing solution ejecting nozzle onto a support rotating at a constant speed while scanning the developing solution ejecting nozzle at a constant speed (a dynamic dispense method).

The rinse treatment (washing treatment) using a rinse liquid can be performed according to a known rinse method. Examples of the rinse treatment method include a method of continuously ejecting a rinse liquid onto a support rotating at a constant speed (a rotary coating method), a method of immersing a support in a rinse liquid for a predetermined time (a dip method), and a method of spraying a rinse liquid to the surface of a support (a spray method).

In the rinse treatment, water rinse using pure water is preferable in a case of an alkali developing solution. Further, it is preferable to use a rinse liquid containing an organic solvent in a case of an organic developing solution.

In the above-described method of forming pattern according to the embodiment, the negative-tone photosensitive resin composition according to the first aspect is used, and thus it is possible to improve adhesion properties to the surface of the support (in particular, metal substrate such as Cu, Au, and Cr) and to form a fine pattern.

For example, according to an LS pattern, it is possible to reliably form a pattern having a line width of 10 μm or less without falling down.

### EXAMPLES

Hereinafter, the present invention will be described in more detail with reference to examples, but the present invention is not limited to the examples.

### Preparation of Photosensitive Resin Composition

### Examples 1 to 9 and Comparative Examples 1 to 3

Respective components listed in Table 1 were mixed and dissolved, and the solution was filtered using a PTFE filter (a pore diameter of 1 μm, manufactured by Pall Corporation) to prepare each negative-tone photosensitive resin composition (a MEK solution having a solid content of 77% by mass) of each example.

TABLE 1

| | Component (A) | | Component (I) | | | Component (T) | | | | |
|---|---|---|---|---|---|---|---|---|---|---|
| | Compo- | | Compo- | Compo- | Compo- | Compo- | Compo- | Compo- | Compo- | Compo- |
| | nent | Compound | nent | nent | nent | nent | nent | nent | nent | nent |
| | (A1) | (m2) | (I1) | (I2) | (I3) | (T1) | (T2) | (C) | (M) | (S) |
| Example 1 | (A1)-1 | (A)-2 | — | (I2)-1 | — | (T1)-1 | — | — | — | (S)-1 |
| | [90] | [10] | | [0.6] | | [0.5] | | | | [30] |
| Example 2 | (A1)-1 | (A)-2 | — | (I2)-1 | (I3)-1 | (T1)-1 | — | — | — | (S)-1 |
| | [90] | [10] | | [0.6] | [0.02] | [0.5] | | | | [30] |
| Example 3 | (A1)-1 | (A)-2 | — | (I2)-1 | — | (T1)-1 | — | — | — | (S)-1 |
| | [90] | [10] | | [0.6] | | [0.5] | | | | [30] |
| Example 4 | (A1)-1 | (A)-2 | (I1)-1 | — | — | (T1)-1 | — | — | — | (S)-1 |
| | [90] | [10] | [2.5] | | | [0.5] | | | | [30] |
| Example 5 | (A1)-1 | (A)-2 | — | (I2)-1 | — | (T1)-2 | — | — | — | (S)-1 |
| | [90] | [10] | | [0.6] | | [0.5] | | | | [30] |
| Example 6 | (A1)-1 | (A)-2 | — | (I2)-1 | — | (T1)-3 | — | — | — | (S)-1 |
| | [90] | [10] | | [0.6] | | [0.5] | | | | [30] |
| Example 7 | (A1)-2 | (A)-2 | — | (I2)-1 | — | (T1)-1 | — | — | — | (S)-1 |
| | [90] | [10] | | [0.6] | | [0.5] | | | | [30] |
| Example 8 | (A1)-1 | (A)-2 | — | (I2)-1 | — | (T1)-1 | — | (C)-1 | — | (S)-1 |
| | [93] | [7] | | [0.6] | | [0.5] | | [3.0] | | [30] |
| Example 9 | (A1)-1 | (A)-2 | — | (I2)-1 | — | (T1)-1 | — | — | (M)-1 | (S)-1 |
| | [87.5] | [12.5] | | [0.7] | | [0.6] | | | [25] | [38] |
| Comparative | (A1)-1 | (A)-2 | — | (I2)-1 | — | — | — | — | — | (S)-1 |
| Example 1 | [90] | [10] | | [0.6] | | | | | | [30] |
| Comparative | (A1)-1 | (A)-2 | — | (I2)-1 | — | — | — | — | (M)-1 | (S)-1 |
| Example 2 | [87.5] | [12.5] | | [0.7] | | | | | [25] | [38] |
| Comparative | (A1)-1 | (A)-2 | — | (I2)-1 | — | — | (T2)-1 | — | — | (S)-1 |
| Example 3 | [90] | [10] | | [0.6] | | | [0.1] | | | [30] |

In Table 1, each abbreviation has the following meaning. The numerical values in the parentheses are the content (parts by mass, in terms of solid content) of the respective components.

(A1)-1: epoxy group-containing resin represented by Chemical Formula (A11), trade name “JER157s70”, manufactured by Mitsubishi Chemical Corporation

(A1)-2: epoxy group-containing resin having a repeating structure of a constitutional unit represented by Chemical Formula (A12), trade name “EPICLON N-770”, manufactured by DIC Corporation

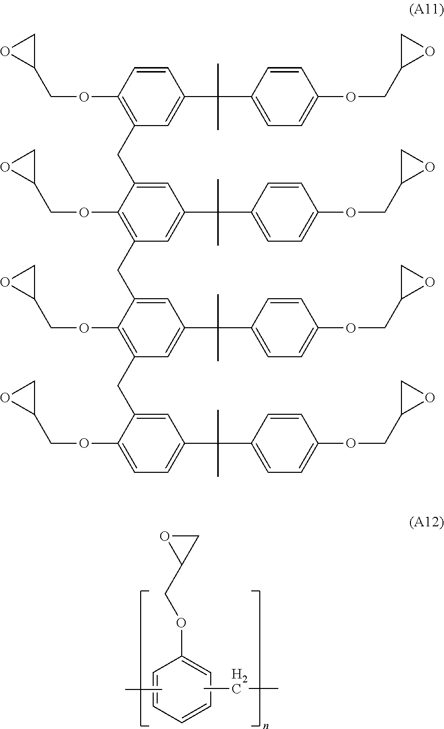

(A)-2: compound represented by Chemical Formula (m1-1), trade name “TEPIC-VL”, manufactured by Nissan Chemical Industries, Ltd.

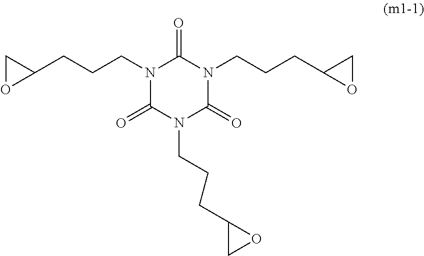 [SMILES: O=c1n(CCCC2CO2)c(=O)n(CCCC2CO2)c(=O)n1CCCC1CO1]

(I1)-1: cationic polymerization initiator represented by Chemical Formula (I1-1), trade name “CPI-310B”, manufactured by San-Apro Ltd.

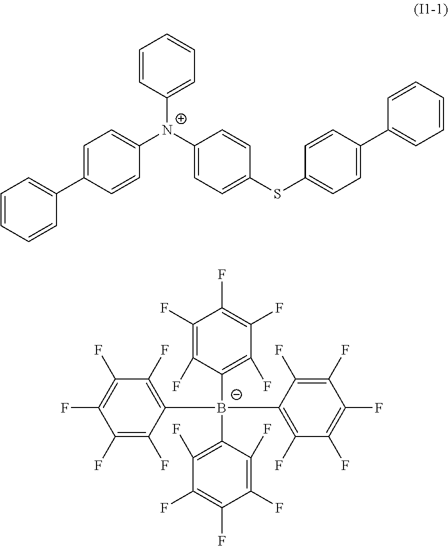 [SMILES: c1ccc(-c2ccc(Sc3ccc([NH+](c4ccccc4)c4ccc(-c5ccccc5)cc4)cc3)cc2)cc1 ; Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F]

(I2)-1: cationic polymerization initiator represented by Chemical Formula (I2-1), trade name “CPI-410S”, manufactured by San-Apro Ltd.

(I3)-1: cationic polymerization initiator represented by Chemical Formula (I3-1-1), trade name “HS-1CS”, manufactured by San-Apro Ltd.

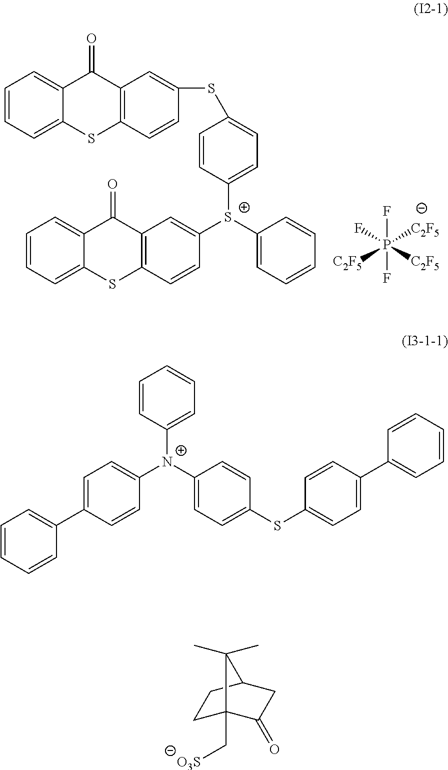

(T1)-1 to (T1)-3: polyfunctional thiol compounds represented by Chemical Formulae (T1-1) to (T1-3) respectively

(T2)-1: mercaptobenzimidazole

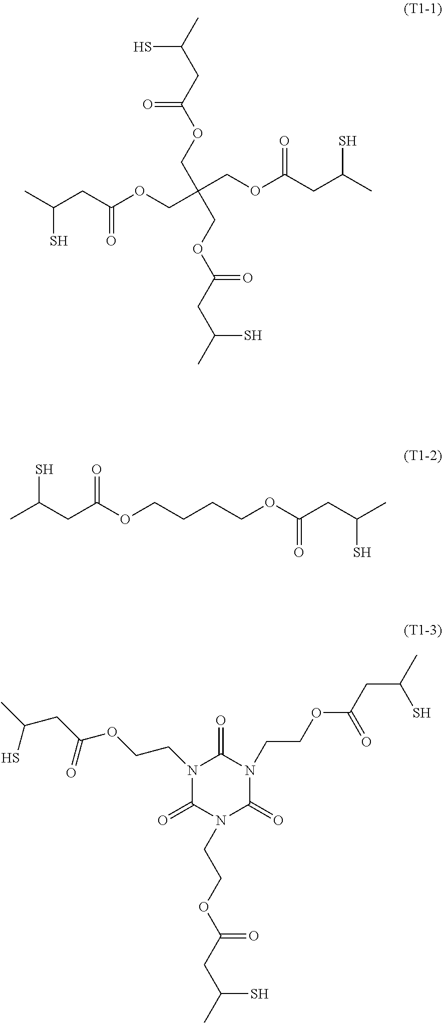

(M)-1: methyl ethyl ketone dispersion liquid having silica component concentration of 31% by mass (trade name “MEK-EC-2130Y”, manufactured by Nissan Chemical Industries, Ltd.), primary particle diameter cp of 15 nm (volume average value)

(C)-1: γ-glycidoxypropyltrimethoxysilane represented by Chemical Formula (C-1), trade name “OFS-6040”, manufactured by Dow Corning Toray Co., Ltd.

(S)-1: methyl ethyl ketone (MEK)

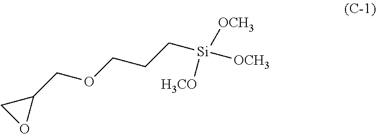 [SMILES: CO[Si](CCCOCC1CO1)(OC)OC]

<Production of Photosensitive Resist Film>

A photosensitive resin film having a thickness of 20 μm was formed on a PET base film having a thickness of 50 μm by using the photosensitive resin composition, and a PET cover film of 25 μm was laminated on the photosensitive resin film to obtain a photosensitive resist film.

<Method of Forming Pattern (1)>

Film Formation Step:

The cover film on the photosensitive resin film in the obtained photosensitive resist film was peeled off, and the peeled surface was laminated on a Cu sputtered substrate by using a roll laminator.

Exposure Step:

Subsequently, the base film in contact with the photosensitive resin film was peeled off, and exposure of 200 mJ/cm² in terms of i-rays was performed by a ghi broadband exposure apparatus through a photomask. After that, post exposure bake (PEB) was performed on a hot plate at 90° C. for 5 minutes.

Development Step:

Subsequently, the exposed Cu sputtered substrate was subjected to puddle development with PGMEA to form a negative-tone pattern.

As a result, an LS pattern having a line width of 4, 6, 8, 10, 15, and 20 μm and a space width of 20 μm was formed.

[Resolution (μm)]

In the <Method of forming pattern (1)>, critical resolution (μm) of a line without pattern delamination and pattern falling was evaluated by using an optical microscope. The result is shown in Table 2 as “Resolution (μm).

<Method of Forming Pattern (2)>

In the same method as that of the <Method of forming pattern (1)>, a square pattern in the shape of a cube of 100 μm was formed.

[Shear Strength]

In the square pattern obtained by the <Method of forming pattern (2)>, a peak strength at which the pattern was peeled off when shearing was applied horizontally from the side of the pattern with a 100-μm shear tool of a bond tester (trade name: Condor Sigma, manufactured by XYZTEC Inc.) was measured.

The result is shown in Table 2 as “Shear strength (N)”.

TABLE 2

| | Resolution (μm) | Shear strength (N) |
|---|---|---|
| Example 1 | 4 | 0.17 |
| Example 2 | 6 | 0.14 |
| Example 3 | 4 | 0.17 |
| Example 4 | 6 | 0.16 |
| Example 5 | 6 | 0.15 |
| Example 6 | 6 | 0.14 |
| Example 7 | 6 | 0.16 |
| Example 8 | 4 | 0.18 |
| Example 9 | 6 | 0.19 |
| Comparative Example 1 | 15 | 0.09 |
| Comparative Example 2 | 15 | 0.08 |
| Comparative Example 3 | 15 | 0.10 |

From the result shown in Table 2, according to the negative-tone photosensitive resin composition of the example, it was confirmed that adhesion properties to the support were good, and thus it was possible to form a fine pattern.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A negative-tone photosensitive resin composition comprising:
an epoxy group-containing resin (A);
a cationic polymerization initiator (I); and
a polyfunctional thiol compound (T).

2. The negative-tone photosensitive resin composition according to claim 1, wherein a content of the polyfunctional thiol compound (T) is 0.01 to 5 parts by mass with respect to 100 parts by mass of the epoxy group-containing resin (A).

3. The negative-tone photosensitive resin composition according to claim 1, wherein the polyfunctional thiol compound (T) comprises a compound represented by Formula (T1): 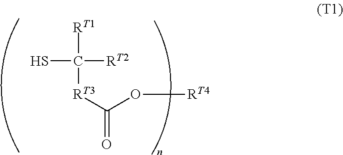
wherein R^{T1} and R^{T2} each independently represents a hydrogen atom or an alkyl group having 1 to 5 carbon atoms; R^{T3} represents a single bond or an alkylene group having 1 to 5 carbon atoms; R^{T4} represents an n-valent hydrocarbon group; and n represents an integer of 2 to 4.

4. A photosensitive resist film comprising a base film, a photosensitive resin film formed from the negative-tone photosensitive resin composition according to claim 1, and a cover film laminated in this order.

5. A method of forming a pattern comprising:
forming a photosensitive resin film on a support using the negative-tone photosensitive resin composition according to claim 1;
exposing the photosensitive resin film; and
developing the exposed photosensitive resin film to form a negative-tone pattern.

6. A method of forming a pattern comprising:
forming a photosensitive resin film on a support using the photosensitive resist film according to claim 4;
exposing the photosensitive resin film; and
developing the exposed photosensitive resin film to form a negative-tone pattern.

7. The method of forming a pattern according to claim 5, wherein the support includes a metal surface and the photosensitive resin film is formed on the metal surface.

8. The method of forming a pattern according to claim 6, wherein the support includes a metal surface and the photosensitive resin film is formed on the metal surface.

9. The method of forming a pattern according to claim 5, wherein the negative-tone pattern is a line-and-space pattern having a line width of 10 μm or less.

10. The method of forming a pattern according to claim 6, wherein the negative-tone pattern is a line-and-space pattern having a line width of 10 μm or less.
